(19) United States
(12) Patent Application Publication
(10) Pub. No.: US 2016/0055125 A1
(43) Pub. Date: Feb. 25, 2016

(54) METHODS AND SYSTEMS FOR DETERMINING GLOBAL SENSITIVITY OF A PROCESS

(71) Applicant: The Arizona Board of Regents on Behalf of the University of Arizona, Tucson, AZ (US)

(72) Inventors: Seyed Saman RAZAVI, Saskatoon (CA); Hoshin V. GUPTA, Tucson, AZ (US)

(21) Appl. No.: 14/752,268

(22) Filed: Jun. 26, 2015

Related U.S. Application Data
(60) Provisional application No. 62/018,197, filed on Jun. 27, 2014.

(51) Int. Cl. G06F 17/18; G06F 17/50

(52) U.S. Cl. CPC G06F 17/18; G06F 17/5009

(57) ABSTRACT

Systems and methods for determining the sensitivity of a model to a factor are disclosed. A directional variogram corresponding to a response surface of the model is determined. The variogram is then output as an indication of the sensitivity of the model.

### BACKGROUND

1. Technical Field Text

Embodiments of the invention relate to computer implemented systems and methods for performing global sensitivity analysis.

2. Background Information

Computer simulation models are essential components of research, design, development, and decision-making in science and engineering. With continuous advances in understanding and computing power, such models are becoming more complex with increasingly more factors to be specified (model parameters, forcings, boundary conditions, etc.). To facilitate better understanding of the role and importance of different model factors in producing the model responses, ‘Sensitivity Analysis’ (SA) is helpful. There are a variety of approaches towards sensitivity analysis that formally describe different “intuitive” understandings of the sensitivity of one or multiple model responses to different factors such as model parameters or forcings. Further, the objectives of SA can vary with application, and a survey of the literature reveals that it has been used to explore various aspects and questions pertaining to model development and application. For example, some of the different (in cases complimentary) objectives of SA include:
a. Assessment of Similarity: Diagnostic testing and evaluation of similarities between the functioning of the model and the underlying system, for fidelity assessment of the model structure and conceptualization.
b. Factor Importance and Function: Identification, prioritization, and screening of the factors that are more influential and contribute most significantly to variability and other characteristics of model/system response.
c. Regions of Sensitivity: Location and characterization of regions in the factor space where the model/system presents the highest variability in response to variations in the factors. This is instrumental in model calibration.
d. Factor Interdependence: Investigation of the nature and strength of interactions between the factors, and the degree to which factors intensify, cancel, or compensate for the effect of each other.
e. Factor and Model Reduction: Identification of the non-influential factors and/or insensitive (possibly redundant) components of model structure, usually so they can be constrained or removed so as to simplify the model/analysis.
f. Uncertainty Apportionment: Quantitative attribution of the uncertainty in model response to different factors (sources of uncertainty), with the goal of identifying where best to focus efforts at improved factor characterization so as to achieve reductions in total uncertainty.

A variety of methods for SA have been presented based in different philosophies and theoretical definitions of sensitivity. The methods range from simple ‘local derivative’ and ‘one-factor-at-a-time (OAT)’ procedures to rigorous Sobol-type ‘analysis-of-variance’ approaches. Their applicability and suitability in regards to the different objectives outlined above vary. In general, different SA methods focus on different properties of the model response and can therefore lead to different, sometimes conflicting, conclusions about the underlying sensitivities. Their computational efficiency can also vary significantly, where ‘efficiency’ is commonly assessed in terms of the number of samples/experiments (model simulation runs) required for the method to generate statistically robust and stable results.

The significance of SA and the associated challenges in the context of complex models such as Environmental and Earth System modeling cannot be understated. Such models are rapidly becoming increasingly more complex and computationally intensive, and are growing in dimensionality (both process and parameter), as they progressively and more rigorously reflect our growing understanding (or hypotheses) about the underlying real-world systems they are constructed to represent. SA becomes, therefore, a critical tool in the development and application of such models. Its widespread applicability can be inhibited, however, by the associated computational expense, and so the development of strategies for SA that are both effective and efficient is of paramount importance.

Overall, a user must carefully consider at least three questions when selecting and applying a method of SA to a given problem:

a. What is the objective of performing sensitivity analysis?

b. What is the intended definition for sensitivity?

c. What is the available computational budget for sensitivity analysis?

Among these, the second question is perhaps the most important as it is typically non-trivial and requires a clear and careful specification of the metric(s) to be used for evaluation of model behavior or performance. In general, the significance of this issue has been largely ignored in the literature regarding SA.

### Local (Point-Based) Sensitivity Analysis of Model Response (LSA-MR)

A “response surface” of a model refers to a line, plane, or hyper-plane that represents a target response of the model (a state or output variable or a performance metric) with respect to one, two, or several factors of interest (e.g., a model parameter or input variable). FIG. 1 shows a simple hypothetical example of a 2-factor response surface 100, such as might be found in a typical textbook. The response surface 100 of a model encapsulates and summarizes a variety of information regarding the underlying characteristics of the model, including sensitivities and factor interactions.

Traditionally, the sensitivity of a model response to a factor is defined as the ‘rate of change (slope)’ of the response in the direction of increasing values of that factor. Suppose that the response of the model is represented by a function as:

y=ƒ(x₁, . . . ,xₙ) (Eq-1)

where y is the model response and x₁, . . . , xₙ are the factors of interest varying in the n-dimensional hypercube (i.e., factor space) bounded between x₁^{min}, . . . , xₙ^{min} and x₁^{max}, . . . , xₙ^{max}. The rate of change, sᵢ, of the response y with respect to xᵢ (where 1≦i≦n) can be evaluated at a specific point (x₁*, . . . , xₙ*) in the factor space as the partial derivative of y with respect to xᵢ at that location:

$${s}_{i} = {( \frac{\partial y}{\partial {x}_{i}} )}_{( {x}_{1}^{*} , … , {x}_{n}^{*} )} \qquad ( Eq \text{-} 2 )$$

Note that sᵢ is sometimes referred to as the ‘sensitivity coefficient’, and relates only to the independent effect of factor xᵢ, when all other factors are held constant. To consider the co-varying effects of multiple factors, the sensitivity of the model response to ‘interactions’ among the factors is defined using higher-order partial derivatives. For example, the two-factor interaction between xᵢ and xⱼ (where i≠j and 1≦i,j≦n) on the model response is represented using second-order partial derivatives, and is interpreted as the rate of change of slope in the direction of xᵢ as we move in the direction of xⱼ (and vice versa). Similarly, the sensitivity due to three-factor interactions, such as between xᵢ, xⱼ, and xₖ (where i≠j≠k and 1≦i,j,k≦n) is defined using third-order partial derivatives and interpreted as the change in the two-factor interaction of xᵢ and xⱼ as we change xₖ. At a given point (x₁*, . . . , xₙ*), such two- and three-factor interactions, sᵢⱼ and sᵢⱼₖ, are computed as:

$$\begin{matrix}{s}_{ij} = {( \frac{{\partial }^{2} y}{\partial {x}_{j} \partial {x}_{i}} )}_{( {x}_{1}^{*} , … , {x}_{n}^{*} )} & ( Eq \text{-} 3 ) \\ {s}_{ijk} = {( \frac{{\partial }^{3} y}{\partial {x}_{k} \partial {x}_{j} \partial {x}_{i}} )}_{( {x}_{1}^{*} , … , {x}_{n}^{*} )} & ( Eq \text{-} 4 )\end{matrix}$$

So, at any given point in the n-dimensional factor space, 2ⁿ−1 sensitivity measures can be calculated including n slopes,

$$( \begin{matrix}n \\ 2\end{matrix} )$$

two-factor interactions,

$$( \begin{matrix}n \\ 3\end{matrix} ) ,$$

three-factor interactions, . . . , and one n-factor interaction. This practice of deriving point-based sensitivity measures is sometimes called ‘local sensitivity analysis’, because the resulting assessment of sensitivity will, in general, only be valid locally in the close vicinity of the ‘base point’ in the factor space; the exception is when the response surface is an approximately linear function.

### Local (Point-Based) Sensitivity Analysis of Model Performance (LSA-MP)

The method of Local (Point-Based) Sensitivity Analysis of Model Performance (LSA-MP) is both powerful and commonly used, and the majority of such applications compute only the first-order partial derivatives. However, in the context of environmental modeling we are typically interested in the sensitivity of one or more metrics of model performance (e.g., that measure distance between the model simulations and observed data) to various factors, model parameters, boundary conditions, or modeling constraints etc.

In such cases we have a function ‘optimization’ problem, where the response surface (of the performance metric) will typically contain one or more stationary points at which all of the first-order partial derivatives are zero. In such cases, sensitivity can instead be characterized in terms of the matrix of second-order partial derivatives (the so-called Hessian matrix) evaluated at the stationary point where, for example

$$\frac{{\partial }^{2} y}{\partial {x}_{i}^{2}}$$

quantifies the curvature of the response surface in direction of the i^{th} factor and

$$\frac{{\partial }^{2} y}{\partial {x}_{i} \partial {x}_{j}} ,$$

quantifies the interaction effects. Importantly, the Hessian matrix plays an important role in the context of ‘gradient-based’ optimization and can be related to the precision of the ‘optimal’ parameter estimates (confidence intervals) in the context of Likelihood Theory.

### Numerical Approximations of the Derivatives

In a significant fraction of Earth Science models, their complexity makes it difficult (even expensive) to program and analytically compute the required derivatives, so it is common to estimate their values numerically via finite difference methods that approximate ∂xᵢ by Δx₁ over some small distance. For example, the first order sensitivity coefficient sᵢ in Eq-2 can be numerically approximated as:

$$\hat{{s}_{1}} = ( \frac{\begin{matrix}y ( {x}_{1}^{*} , … , {x}_{i}^{*} + Δ {x}_{i} , … , {x}_{n}^{*} ) - \\ y ( {x}_{1}^{*} , … , {x}_{i}^{*} , … , {x}_{n}^{*} )\end{matrix}}{Δ {x}_{i}} ) \qquad ( Eq \text{-} 5 )$$

In practice, the size of Δxᵢ is usually selected in an ad-hoc manner. However, for significantly non-linear responses the resulting interpretation of sensitivity can itself be significantly sensitive to the size of Δxᵢ. Further, numerical derivation of second- and higher-order partial derivatives can require large numbers of model runs. In certain cases, (including model calibration using performance metrics such as mean squared error), the Hessian matrix can be approximated using computations involving only first-order partial derivatives, resulting in significant computational savings.

### Global (Population Sample-Based) Sensitivity Analysis (GSA)

Local (point-based) sensitivity analysis has a unique definition and theoretical basis, but typically provides only a limited view of model sensitivity because the results (and hence interpretation) can vary with location in the factor space. Methods of so-called ‘Global’ sensitivity analysis (GSA) attempt to provide more general results by characterizing the nature of response sensitivity over the entire factor space. However, this problem of generalizing local sensitivity measures to represent ‘global’ properties (i.e., to somehow reflect the broader characteristics of sensitivity over a domain of interest) is not trivial and, so far, no unique and certain definition for global sensitivity exists.

In general, methods for GSA compute their indicators of sensitivity using ‘values’ (of something) computed at a number of different points sampled across the domain of interest (i.e. a sample population), where the sample locations are picked (in some way) to be ‘representative’ of the entire domain; for example in Sobol Analysis the ‘something’ is typically a metric of model performance (a function value such as ‘mean squared error’) and a variety of strategies for generating representative samples have been proposed (REFS). Therefore, GSA is to some extent rooted in the ‘design of experiments’ (DOE), which is a broad family of statistical methods originally developed for designing efficient experiments to acquire representative information when working in the context of costly, noise-prone environments. DOE has since been extended to the ‘design and analysis of computer experiments’ (DACE), which are typically “noise-free” (also called “deterministic”) in the sense that replicating a computer experiment with the same input factors results in identical model response. Consistent with the GSA paradigm, DOE provides a set of tools including factorial designs and regression strategies that facilitate study of the effects of both individual and combined factors on the response variable, while accounting for interaction effects. As such, the terms ‘main effect’ and ‘interaction’ common in the GSA literature originate from DOE where the ‘main effect’ of a factor is defined as the change in response due to the change in the factor when averaged across all levels of the other factors.

In general, the concept of GSA seems rather intuitive, although it can be interpreted differently with context and application. Broadly speaking, GSA attempts to study and quantify ‘how’ and ‘to what extent’ the model response across the factor space is influenced by a particular factor or combination of factors, either individually and/or through interactions with other factors. Since absolute sensitivity can be difficult to quantify (given that it can vary with scaling or transformation of the factor space), it is usual to focus on the relative sensitivity of factors with respect to each other.

Further, one may be interested in a ‘total effect’ sensitivity measure for each factor that integrates over (or encompasses) the so-called ‘direct effect’ and the ‘interaction effects’; the former quantifies the independent effect of a factor (with all other factors prevented from varying) while the latter represents changes in the direct effect due to other factors being allowed to vary across the overall domain.

As an aside, the sparsity-of-effects principle indicates that most systems or processes are usually driven by (are sensitive to) only a subset of factors and their low-order (e.g., second-order) interactions, and that high-order interactions are typically insignificant or negligible. While this may not be true for some models or for all points in the factor space, the principle has significant implications for GSA. Further, even if high-order effects exist, they can be difficult to interpret, and in many cases may not have any actual physical relevance (i.e., they may be spurious artefacts of the modeling and/or system identification process).

### EXAMPLES

Clearly, in any particular modeling application, the type of ‘model response variable’ of interest can influence the characteristics of the associated response surface and thereby the interpretation of a sensitivity analysis. In environmental modeling, the most common form of sensitivity analysis is to investigate the effects of different factors (parameters, inputs, boundary conditions, etc.) on some metric of goodness-of-fit between the simulated value(s) of some system variable and corresponding observations (in some cases the metric can represent an integration over several model responses). This can result in highly non-monotonic and non-smooth response surfaces that can have multiple modes (i.e., ‘regions of attraction’ in the optimization sense). In general, the analysis of a complex problem of this kind will tend to focus on the region (neighborhood) in the factor space where the model best fits the observations. However, in simpler cases such as when investigating a single model response to a relatively small number of variables, the response surface tends to be smoother and more monotonic, and sensitivity over the entire factor space may be of interest.

FIGS. 2-6 represent five sets of examples of one-factor response functions and their first-order derivatives over the factor range. For each figure, we can ask the seemingly simple question “which response functions are more (or less) sensitive to variations over the range of factor x”. These examples illustrate concepts of sensitivity analysis, and the strengths and shortcomings of existing sensitivity analysis approaches.

Example 1, (FIG. 2A) presents three response functions 104, 106, 108 that vary monotonically over the same output range. These functions have been constructed so that, although each has a different value for local sensitivity (first-order derivative value) at any given x value, all three functions have the same average value for ∂y/∂x over the factor range. Note that it is not at all clear how one should rank these functions with regards to ‘overall sensitivity’, and if we were to use average slope as an indicator of ‘global sensitivity’, the functions would all be deemed equally sensitive (average slope over the range=1).

Similarly, example 2 (FIG. 3A) shows three uni-modal functions 110, 112, 114 (each having a single unique minimum) of the kind that might be shown in optimization textbooks (the response surfaces encountered in model calibration will typically be more complex than these). Note that these are idealized depictions, and the discontinuous derivative at x=0 for functions f₂ 112 and f₃ 114 may not actually occur in modeling practice. However, these examples serve to illustrate the point that if y represents how a model performance metric varies over the range of factor x, then we would intuitively deem f₃ 114 to indicate the most sensitive response since it is associated with steeper gradients in the vicinity of the function ‘optimum’ at x=0. Similarly, we would identify f₁ 110 as representing the least sensitive case, with f₂ 112 being somewhere in between. However, if we were to use average slope as an indicator of ‘global sensitivity’, the three functions 110, 112, 114 would again be deemed equally sensitive (average slope over the range=0).

Our third example, (FIG. 4A), presents three functions 116, 118, 120 that cover radically different output ranges but have constant and identical values for absolute local sensitivities (absolute derivative values) across the factor range (except at the singular points where the derivatives change sign). So all three cases have average absolute slope=1. One possible intuitive interpretation is that f₁ 116 represents the situation with highest sensitivity of the response y to variations in factor x, because changes in x control a larger range of the output. However, in some situations, periodicities (multi-modalities) in the response surface may be very important in evaluating the sensitivity of a factor. From the perspective of model calibration, the function f₂ 118 that is characterized by two distinct regions of attraction in the factor domain might be deemed quite ‘sensitive’ to x. Meanwhile f₃ 120 is characterized by significant periodicity and has the exact same average absolute local sensitivity as the other two functions, but may simply represent an insensitive but non-smooth (noisy) model response—non-smoothness of this kind can be common in environmental modeling due to numerical artifacts.

In a similar but slightly more realistic example, FIG. 5A shows two functions 122, 124 that both have average absolute slope=0. Further, they also have identical variance of the value of the response y. In this case, one might intuitively deem f₂ to represent the situation of higher factor sensitivity because it demonstrates both significant periodicity and variation in local sensitivity values across the x range. To understand this, ask yourself the question “which function represents the situation where the value of y changes more rapidly as x is varied over its range?” If one is concerned with the local stability of the response to small changes in factor x then clearly function f₂ 124 represents the situation of higher sensitivity, but if one is concerned mainly with the broad overall change in y over the total range of x, then both functions can be deemed to be fairly similar in that respect.

To conclude our motivational illustrations regarding the difficulty of defining what is meant by sensitivity, we present one more example based on the fact that any periodic (multi-modal) response surface can be decomposed into a set of simpler periodic functions having different amplitude and frequencies (e.g., via Fourier series analysis). FIG. 6A a shows a periodic function ƒ(x), and its decomposition into four constituent modes:

$$f ( x ) = 1.33 - sin ( \frac{2 π x}{40} ) - 0.3 sin ( \frac{2 π x}{11} ) - 0.05 sin ( \frac{2 π x}{2} ) - 0.02 sin ( \frac{2 π x}{0.5} ) \qquad ( Eq \text{-} 6 )$$

where the sinusoidal terms correspond respectively to the functions g₁(x), g₂(x), g₃(x), and g₄(x) shown in FIG. 6A. In addition, FIG. 6B shows the analytical derivative of the original function f(x) 126 with respect to factor x. As can be seen, the component function g₄(x) 128 dominates the contribution to local sensitivity (slope) across the factor range, and could lead an analyst to infer a very large sensitivity. However, if g₄(x) 128 primarily represents noise due to data errors or numerical artefacts, such an interpretation can be highly misleading.

In practice, partial derivatives (and associated sensitivity measures) are typically calculated by finite difference procedures on the basis of some (often arbitrarily chosen) step size Δx. In such situations, the selection of larger Δx values will cause the analysis to be less sensitive to high-frequency roughness in the response surface. We illustrate this in FIG. 6C for the cases where Δx equals 0.5 and 2 (corresponding to the periods of the g₄(x) and g₃(x) waves) and for which the derivative functions are then equivalent to d(g₁(x)+92(x)+g₃(x))/dx and d(g₁(x)+g₂(x))/dx, respectively. When Δx=11, the derivate function is close to d(g₁(x))/dx shown in FIG. 6C. Clearly, interpretation of the sensitivity of ƒ(x) with respect to variations in x can be very different for different Δx values.

### Historical Evolution of Sensitivity Analysis Methods

The earliest approaches to sensitivity analysis were based largely in the use of partial derivatives and the concept of a Taylor series expansion around a base point, and derivative-based LSA methods also have roots in optimization theory. Over the past several decades, numerous attempts to represent the more ‘global’ nature (over the factor domain as opposed to at a specific point) of the sensitivity of model response have been made. Most of these are based in concepts developed for the statistical design of experiments, including the one-factor-at-a-time (OAT) method, factorial design, and regression and correlation analysis. Of course, a preliminary and widely used step in any such analysis is to inspect scatter plots of the model response versus each factor and their correlations for a selected sample of points, thereby revealing basic information about global sensitivities.

### One-Factor-At-a-Time Method (OAT)

The OAT method (probably the simplest of these techniques) computes an approximate local slope (partial derivative) of the response surface around a base point in the factor space. In practice, because the size of the factor change in OAT is typically not very small, the method actually detects larger-scale trends (lower frequency variations) in the response surface. Further, OAT does not detect and measure factor interactions. Nonetheless, the approach is computationally very efficient, requiring only n+1 model runs for an n-dimensional factor space.

### Factorial Design

In ‘full factorial’ designs, the factor space is discretized into a certain number of levels (i.e., grid points) along the direction of each factor and a representative value of model response is computed for each level. All possible combinations of the levels across all factors are then used to estimate the ‘main effects’ of each factor (providing a global measure of first-order sensitivity) and also the ‘interaction effects’ between various combinations of factors (providing global measures of second- and higher-order sensitivities). The degree to which this approach properly represents global sensitivity depends on a number of things, including the selected grid spacing (number of levels for each factor) and the degree of nonlinearity in the underlying response. Further, because an m-level full factorial design in an n-dimensional factor space requires mn model runs, the approach is subject to the curse of dimensionality and computational cost can rapidly become prohibitive as problem dimension increases. To try and mitigate this latter issue, fractional factorial designs that rely on the sparsity-of-effects principle have been proposed; these use a carefully selected sub-sample of the full factorial design to estimate only the main and low-order interaction effects.

### Response Surface Approximation Via Regression

A number of different regression techniques have been used to approximate response surfaces for the purpose of sensitivity analysis, generally using either linear (with or without second-order interaction terms) or quadratic polynomials; such approaches can be classified as ‘response surface methods’. Once the model is fit to a set of points sampled in the factor space (note the connection to factorial design), the coefficients of the regression equation can be interpreted as indices of factor sensitivity—the coefficients of linear and second-order interaction terms correspond to the main and interaction effects respectively, while second-order terms can be used to detect non-linearities in the response.

To sample the factor space, both deterministic and random sampling techniques (e.g., factorial design and Latin hypercube) have been used. However, a major drawback of the regression-based approach is the need to pre-specify an appropriate form for the regression function, and if the regression equation does not fit the underlying response surface well, the sensitivity estimates can be seriously incorrect. Note that scatter plots can be used to help detect poor model fits.

### Model Free Methods

Historically, the methods described above were originally developed for the analysis of physical experiments. In the context of computer-based modeling, it became more affordable to conduct simulation experiments, and led to the development of methods requiring large numbers of samples. Such methods were also motivated by the fact that the degree of linearity, monotonicity, and additivity of the underlying response surface of a complex model cannot generally be known a priori, raising the need for ‘model-free’ methods that make minimal assumptions regarding the shape of the response surface. The rest of this section is dedicated to a brief review of such methods.

### Variance-Based Methods:

Theoretical Basis: Perhaps the most sophisticated approach developed to-date, for defining and quantifying ‘global’ sensitivity, is that of variance-based sensitivity analysis. This approach is based on the idea that the variability (hence variance) of the model response in each factor direction can be used as a direct indicator of factor sensitivity (note that model response is typically quantified using some model performance metric such as mean squared error). Therefore, the contribution of each factor (main or first-order effect), and each possible two- or higher-order interaction (interaction effect), to forming the total variance of the model response is quantified, and the ratio of each contribution to the total variance is interpreted as the measure of sensitivity. Given the model response function presented in Eq-1, the variance of the model response, V(y), can be theoretically decomposed to 2ⁿ−1 components as follows:

V(y)=Σᵢ₌₁ⁿ=Vᵢ+Σᵢ₌₁ⁿ⁻¹Σⱼ₌ᵢ₊₁ⁿVᵢⱼ+Σⱼ₌ᵢ₊₁ⁿ⁻²Σⱼ₌ᵢ₊₁ⁿ⁻¹Σₖ₌ⱼ₊₁ⁿVᵢⱼₖ+ . . . V_{1 . . . n} (Eq-6)

where Vᵢ is the contribution of the i^{th} factor to the total variance excluding its interactions with other factors, Vᵢⱼ is the contribution of the two-factor interaction of the i^{th} and j^{th} factors to the total variance, Vᵢⱼₖ is the contribution of the three-factor interaction of the i^{th}, j^{th}, and kth factors to the total variance, and so on. These components can be computed as Vᵢ=V(E(y|xᵢ)), Vᵢⱼ=V (E(y|xᵢ, xⱼ))−Vᵢ−Vⱼ, and Vᵢⱼₖ=V(E(y|xᵢ, xⱼ, xₖ))−Vᵢ−Vⱼ−Vᵢⱼ−Vᵢₖ−Vⱼₖ. Accordingly, the associated first-, second-, and third-order sensitivity indices are

$${S}_{i} = \frac{{V}_{i}}{V ( y )} , {S}_{ij} = \frac{{V}_{ij}}{V ( y )} , and {S}_{ijk} = \frac{{V}_{ijk}}{V ( y )} .$$

Of particular interest in variance-based sensitivity analysis is the calculation of the ‘total-order’ or ‘total effect’ sensitivity index, S_{Ti}, which sums over the first-order effect of the i^{th} factor and its interactions of any order with any other factors. To circumvent having to compute all the related terms, the total-effect sensitivity index can be alternatively calculated as follows:

$${S}_{Ti} = 1 - \frac{V ( E ( y \vert {x}_{1} , {x}_{2} , … , {x}_{i - 1} , {x}_{i + 1} … , {x}_{n} ) )}{V ( y )} \qquad ( Eq \text{-} 7 )$$

where the numerator consists of all the terms of any order that do not include the i^{th} factor.

Computational Implementation: For simple, analytically tractable functions, the variance-based sensitivity indices can be calculated analytically. The Fourier Amplitude Sensitivity Test (FAST) provides an efficient way to numerically compute variance-based sensitivity indices. However, FAST can provide only first-order sensitivity indices, and a later development called the ‘extended FAST’ (EFAST) allows the computation of total effects.

Perhaps the most popular implementation of variance-based sensitivity analysis is the so-called ‘Sobol method’, named after Ilya M. Sobol′, which is able to provide numerical estimates of first-, higher-order, and total-effect sensitivity indices in a relatively efficient manner based on Monte-Carlo sampling.

There are at least four important characteristics that must be considered when investigating and interpreting the sensitivity of a response surface (metric of model performance) to its parameters/factors: (a) local sensitivities (i.e., first order derivatives), (b) global distribution of local sensitivities (characterized, for example, by their mean and variance), (c) global distribution of model response (characterized, for example by the variance), and (d) the structural organization of the response surface (including its multi-modality and degree of non-smoothness/roughness). As illustrated above, existing SA approaches typically focus on only a few of these aspects while ignoring the others. The variance-based Sobol approach, for example is based entirely on characterizing the global variance of model response, and its decomposition into components associated with individual contributing factors. As such, the Sobol approach is unable to distinguish between response surface structures that might happen to have identical global variance of model response but completely different distributions and spatial organization of the performance metric and its derivatives.

There are two issues that continue to pose major challenges in SA.
a. Ambiguous Characterization of Sensitivity—Different SA methods are based in different philosophies and theoretical definitions of sensitivity. The absence of a unique definition for sensitivity can result in different, even conflicting, assessments of the underlying sensitivities for a given problem.
b. Computational Cost—The cost of carrying out SA can be large, even excessive, for high-dimensional problems and/or computationally intensive models. This cost varies significantly for different methods, where cost (or ‘efficiency’) is commonly assessed in terms of the number of samples (model simulation runs) required for the method to generate statistically robust and stable results.

Thus there exists a need for sensitivity analysis that addresses the dual aspects of effectiveness and efficiency. An assessment should be achieved that is both meaningful and clearly reflective of the objective of the analysis (the first challenge above), while achieving statistically robust results with minimal computational cost (the second challenge above).

### BRIEF SUMMARY

In a first aspect a system for analyzing sensitivity of a model is disclosed. The system includes a computer processer, an input in communication with the computer processor, and non-transitory memory in communication with the processor. The non-transitory memory stores computer executable instructions that when executed by a computer processor implement modules. The modules include: an input module configured to receive data comprising a plurality of values of a model output and, for each value of the model output, corresponding values of input factors resulting in the model output; a variogram construction module configured to construct a directional variogram based on the data received at the input module; and an output module configured to output the directional variogram as a representation of the model sensitivity. In some embodiments, the modules further include a model module configured to model a process. In some embodiments, the modules further include a sampling module configured to generate a plurality of sample points for modeling the process. In some embodiments, the model module is configured to model an environmental system.

In some embodiments, the variogram construction module is further configured to construct a directional variogram for each input factor. In some embodiments, the output module is configured to display the variogram.

In another aspect a method for analyzing the sensitivity of a model is disclosed. The method includes: receiving, by a computer, a plurality of sets of input factor values and for each set, a corresponding model output value; constructing, by a computer, a plurality of directional variograms based on the sets of input factor values and model output values; and outputting the plurality of directional variograms as an indication of model sensitivity. In some embodiments, the method further includes generating a plurality of sample points to use as input factor values.

In some embodiments, the method further includes providing, by a computer, the plurality of sets of input factor values to a model and for each set of input factor values, recording an output value of the model. In some embodiments, the method further includes normalizing the plurality of variograms.

In some embodiments, the plurality of directional variograms include a variogram for each input factor in the sets of input factor values. In some embodiments, outputting the plurality of directional variograms includes displaying each of the variograms on a common graph. In some embodiments the model is an environmental model.

In some embodiments, normalizing the plurality of variograms includes integrating each variogram from zero to a maximum value of an input factor.

In some embodiments, outputting the plurality of variograms includes outputting a plurality of values for each variogram.

In some embodiments, the plurality of values includes a value at ten percent of the factor range and fifty percent of the factor range.

### BRIEF DESCRIPTION OF THE DRAWINGS

FIG. 1 illustrates a hypothetical response surface representing a model response, y, with respect to two factors, x₁ and x₂.

FIG. 2A illustrates a first example of response surfaces, FIG. 2B illustrates the derivative functions of the response surfaces across the factor range, FIG. 2C illustrates the variograms of the response surfaces, and FIG. 2D illustrates the integrated variograms of the response surfaces.

FIG. 3A illustrates a second example of response surfaces, FIG. 3B illustrates the derivative functions of the response surfaces across the factor range, FIG. 3C illustrates the variograms of the response surfaces, and FIG. 3D illustrates the integrated variograms of the response surfaces.

FIG. 4A illustrates a third example of response surfaces, FIG. 4B illustrates the derivative functions of the response surfaces across the factor range, FIG. 4C illustrates the variograms of the response surfaces, and FIG. 4D illustrates the integrated variograms of the response surfaces.

FIG. 5A illustrates a fourth example of response surfaces, FIG. 5B illustrates the derivative functions of the response surfaces across the factor range, FIG. 5C illustrates the variograms of the response surfaces, and FIG. 5D illustrates the integrated variograms of the response surfaces.

FIG. 6A illustrates a fifth example demonstrating the “scale issue” in sensitivity analysis, a non-smooth response surface and its constituent modes, FIG. 6B illustrates the derivative function of the response surface when Δx=dx→0, and FIG. 6C illustrates the example derivative functions for larger Δx values.

FIG. 7A illustrates the relation between a function and its variogram, a one-factor response surface with ten sampling points, FIG. 7B illustrates a mapping of the samples onto a variogram space, FIG. 7C illustrates a mapping of the samples onto a covariogram space, FIG. 7D illustrates the one-factor response surface with fifty sampling points, FIG. 7E illustrates a mapping of the samples onto the variogram space, FIG. 7F illustrates a mapping of the samples onto the covariogram space.

FIG. 8A illustrates an integrated variogram corresponding to FIG. 3D, FIG. 8B illustrates the integrated variogram corresponding to FIG. 4D, and FIG. 8C illustrates the integrated variogram corresponding to FIG. 5D.

FIG. 9A illustrates a comparison of the calculated sensitivities corresponding to FIG. 3A-D, FIG. 9B illustrates the comparison corresponding to FIGS. 4A-D, and FIG. 9C illustrates the comparison corresponding to FIG. 5A-D.

FIG. 10 illustrates the response surface of a test function with six factors.

FIG. 11A illustrates the directional variograms of the test function of FIG. 10, FIG. 11B illustrates the integrated variograms of the test function of FIG. 10, FIG. 11C illustrates the Morris-based mean absolute elementary effects for the test function of FIG. 10, and FIG. 11D illustrates the Morris-based mean actual elementary effects for the test function of FIG. 10.

FIG. 12 illustrates the measure of sensitivity of the test function of FIG. 10.

FIG. 13 illustrates the robustness of the variogram methodology.

FIG. 14A illustrates the result of bootstrapping to evaluate the level of confidence for the variograms corresponding to a variogram of a test function having 10 star points, FIG. 14B illustrates the result of bootstrapping corresponding to an integrated variogram of the test function having 10 star points, FIG. 14C illustrates the result of bootstrapping corresponding to a variogram of a test function having 50 star points, and FIG. 14D illustrates the result of bootstrapping corresponding to an integrated variogram of the test function having 50 star points.

FIG. 15A illustrates the directional variograms for a five factor model, FIG. 15B illustrates the integrated variograms, FIG. 15C illustrates the Morris-based mean absolute elementary effects, and FIG. 15D illustrates the Morris-based mean actual elementary effects.

FIG. 16 illustrates the measure of sensitivity of the model of FIG. 15.

FIG. 17 illustrates a variogram for a forty-five factor model.

FIG. 18A illustrates the degree of correspondents between the variogram method and conventional methods at comparable computational budgets corresponding to the degree of correspondence between the IVARS and the VARS-TO at a lower computational budget, FIG. 18B illustrates the degree of correspondents corresponding to the degree of correspondence between the IVARS and the VARS-TO at a higher computations budget, FIG. 18C illustrates the degree of correspondents corresponding to the degree of correspondence between the SOBOL-TO and the VARS-TO at a lower computational budget, and FIG. 18D illustrates the degree of correspondents corresponding to the degree of correspondence between the SOBOL-TO and the VARS-TO at a higher computational budget.

FIG. 19A illustrates the confidence intervals for the sensitivity of the model of FIG. 17 corresponding to the confidence for the VARS-based sensitivity metric for each parameter at a lower computational budget, FIG. 19B illustrates the confidence intervals corresponding to the confidence for the VARS-based sensitivity metric for each parameter at a higher computational budget, FIG. 19C illustrates the confidence intervals corresponding to the bootstrap-based estimates of reliability on the parameter rankings at a lower computational budget, and FIG. 19D illustrates the confidence intervals corresponding to the bootstrap-based estimates of reliability on the parameter rankings at a higher computational budget.

FIG. 20A illustrates illustrates the confidence interval for the sensitivity of the model of FIG. 17 corresponding to the confidence for the SOBOL based sensitivity metric for each parameter and FIG. 20B illustrates the confidence interval corresponding to the bootstrap-based estimates of reliability on the parameter rankings.

FIG. 21A illustrates the confidence interval for the sensitivity of the model of FIG. 17 corresponding to the confidence for the Morris based sensitivity metric for each parameter and FIG. 21B illustrates the confidence interval corresponding to the bootstrap-based estimates of reliability on the parameter rankings.

FIG. 22A illustrates the stability and robustness of implementations of VARS, Sobol, and Morris with increasing computational budget corresponding to VARS, FIG. 22B illustrates the stability and robustness corresponding to Sobol, and FIG. 22C illustrates the stability and robustness corresponding to Morris.

FIG. 23 illustrates an example schematic of an embodiment of a computing device that may be used to practice the claimed subject matter.

FIG. 24 illustrates a high level flowchart of a method for determining the sensitivity of a model.

FIG. 25 illustrates a high level flowchart of a method for determining the sensitivity of a factor of a model.

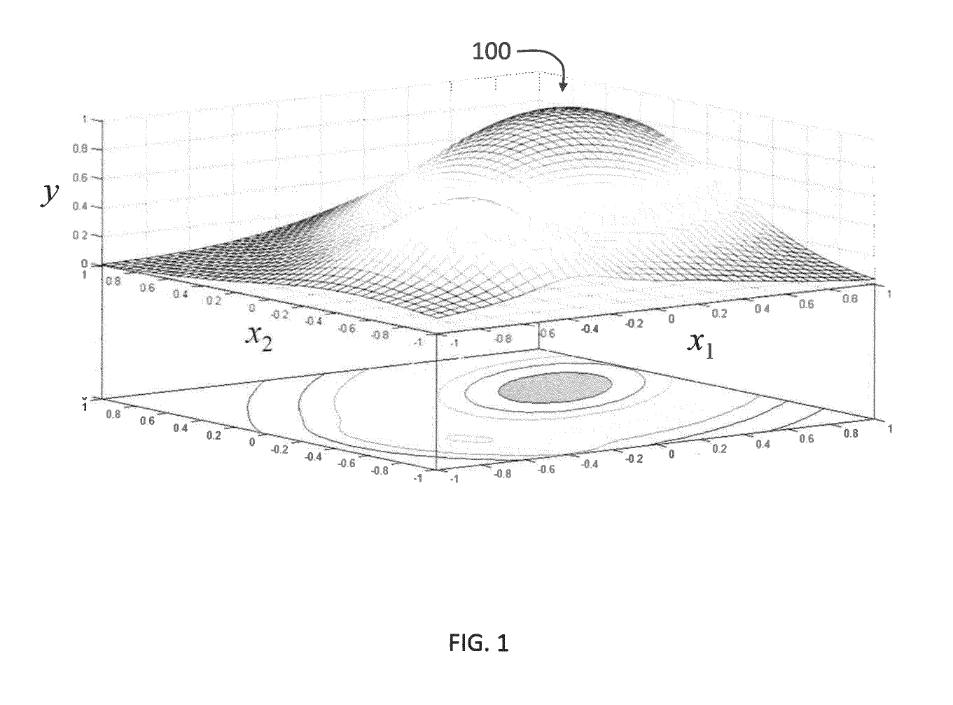

### DETAILED DESCRIPTION

### Variograms and Covariograms

In the field of spatial statistics, a variogram is a function that characterizes the spatial covariance structure of a stochastic process. It is defined as the variance of the differences between response surface values computed at (a large number of) pairs of points at different locations across the factor space. In adopting this concept for the analysis of response surface sensitivity, it is assumed that the model performance metric can be treated as a realization of a spatially stochastic process.

Now, consider two locations A and B with locations x^{A} and x^{B} in the n-dimensional factor space, where x={x₁, . . . , xₙ}. Then, for the response surface represented by Eq-1:

E(y(x))=μ_{y} (Eq-8)

V(y(x^{A})−y(x^{B}))=2γ(x^{A}−x^{B}) (Eq-9)

COV(y(x^{A}),y(x^{B}))=C(x^{A}−x^{B}) (Eq-10)

where E, V, and COV represent expected value, variance, and covariance, respectively, and γ(•) and C(•), called a “variogram” and a “covariogram” respectively, are functions of only the increment x^{A}−x^{B}. Eq-8 is known as the ‘constant mean assumption’. A stochastic process satisfying Eq-8 and Eq-9 is said to be ‘intrinsic stationary’ and when satisfying Eq-8 and Eq-10 is said to be ‘second-order or wide-sense stationary’. Notably, the class of second-order stationary processes is strictly contained in the class of intrinsic stationary processes.

Now, defining h=x^{A}−x^{B} so that h={h₁, h₂, . . . , hₙ} the ‘multi-dimensional variogram’ can be written as:

γ(h)=½V(y(x+h)−y(x)) (Eq-11)

and under the constant mean assumption (intrinsic stationary process) this can be re-written as:

γ(h)=½E[(y(x+h)−y(x))²] (Eq-12)

Further, for a response surface having a closed-form functional expression, the multi-dimensional variogram can be analytically derived as:

$$γ ( h ) = \frac{1}{2 A} {\int }_{Ω} {( y ( x + h ) - y ( x ) )}^{2} d x \qquad ( Eq \text{-} 13 )$$

where ∫_{Ω}(•) dx represents a multiple integral over the factor space such that dx=dx₁ . . . dxₙ, Ω=[x_{i=1:n}^{min}, x_{i=1:n}^{max}−h_{i=1:n}]ⁿ, and A=Πᵢ₌₁ⁿ(xᵢ^{max}−xᵢ^{min}). The variogram (Eq-12) is classically estimated by sampling y(x) at a number of locations, x, across the domain of the factor space so that:

$$y ( h ) = \frac{1}{2 \vert N ( h ) \vert} {\sum }_{( i , j ) ∈ N ( h )} {( y ( {x}_{i} ) - y ( {x}_{j} ) )}^{2} \qquad ( Eq \text{-} 14 )$$

where N(h) denotes the set of all possible pairs of points x^{A} and x^{B} in the factor space, such that |x^{A}−x^{B}|=h, and |N(h)| is the number of pairs in the set.

The covariance structures along the direction of a given factor is used to assess sensitivity of that factor. ‘Directional Variograms’ are of particular interest, where the directional variogram γ(hᵢ) with respect to the i^{th} factor is a one-dimensional function, equivalent to γ(h) when hⱼ=0 for all j≠i. Directional variograms characterize useful information regarding the sensitivity of the response surface to each of the factors and form the building blocks of “Variogram Analysis of Response Surfaces” or VARS.

Further, when the underlying stochastic process is assumed to be isotropic, the variogram can be represented as a one-dimensional function of the distance ∥h∥ which indicates the length of vector h. This variogram, denoted by γ(∥h∥), is referred to as the ‘Overall Variogram’.

### CONCEPTUAL EXAMPLES

### Points to Pairs: Numerical Calculation of Variograms and Covariograms

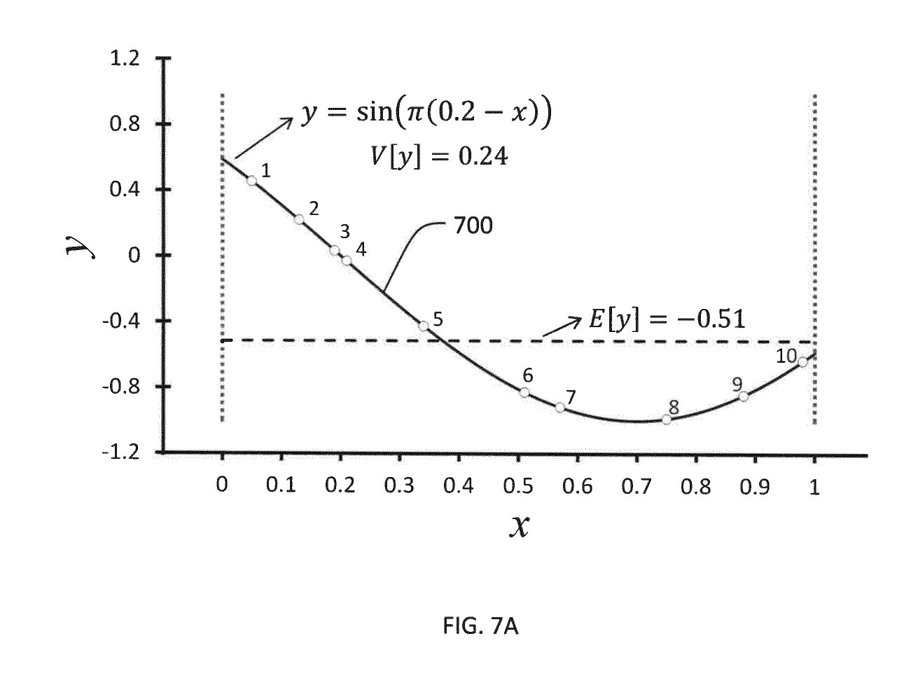

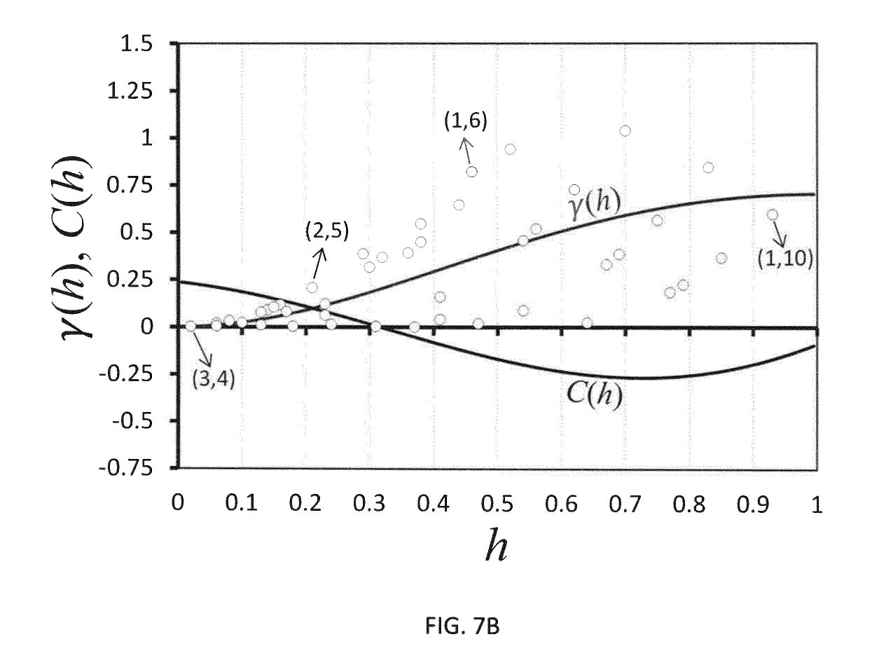

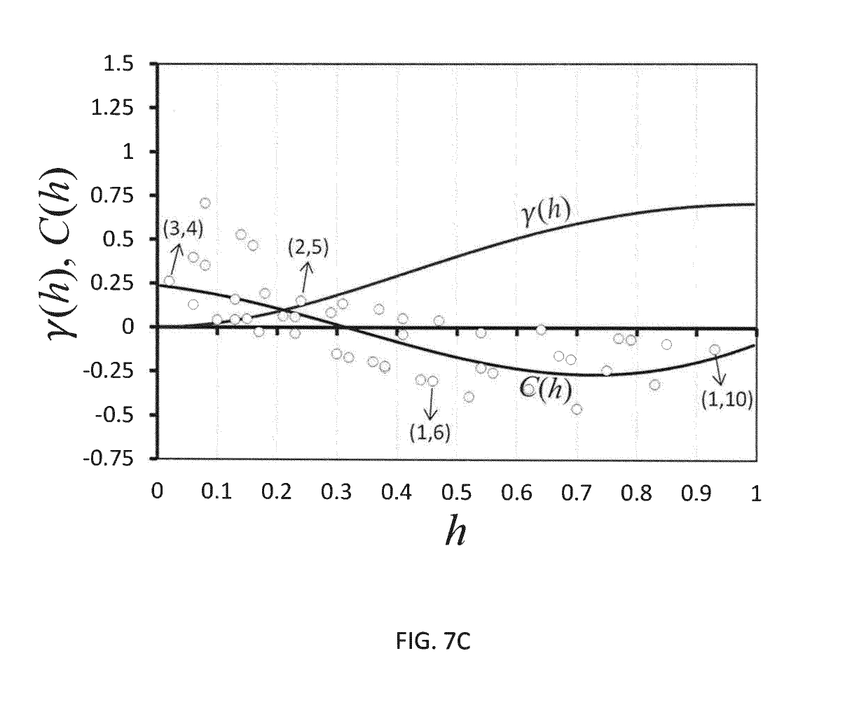

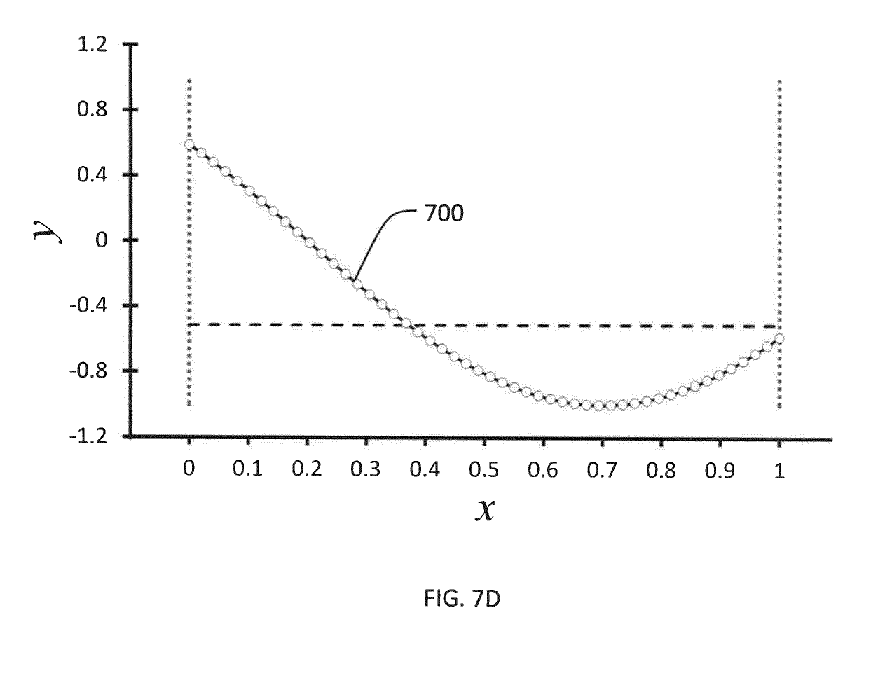

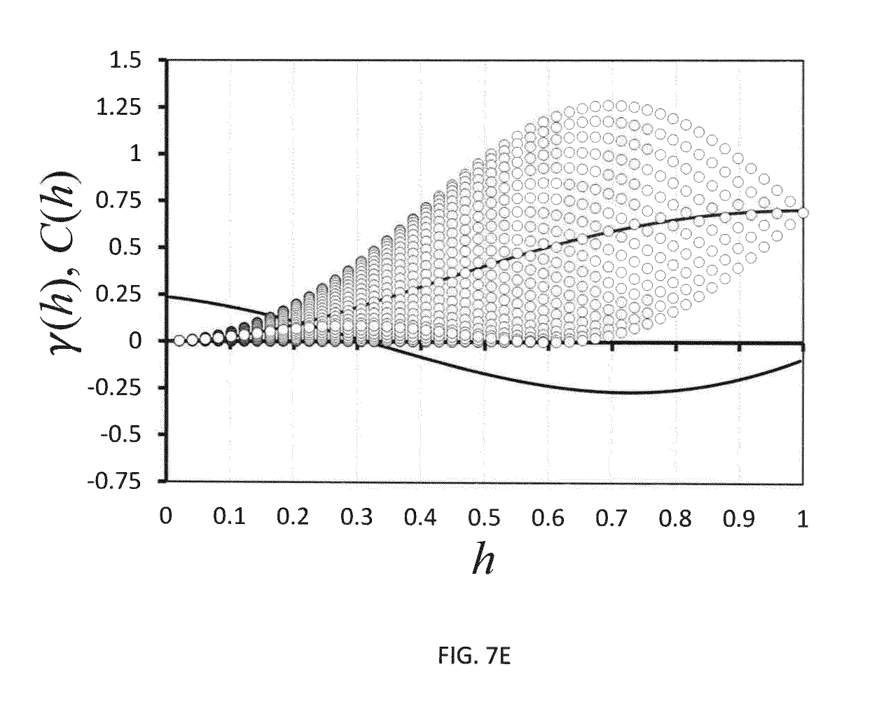

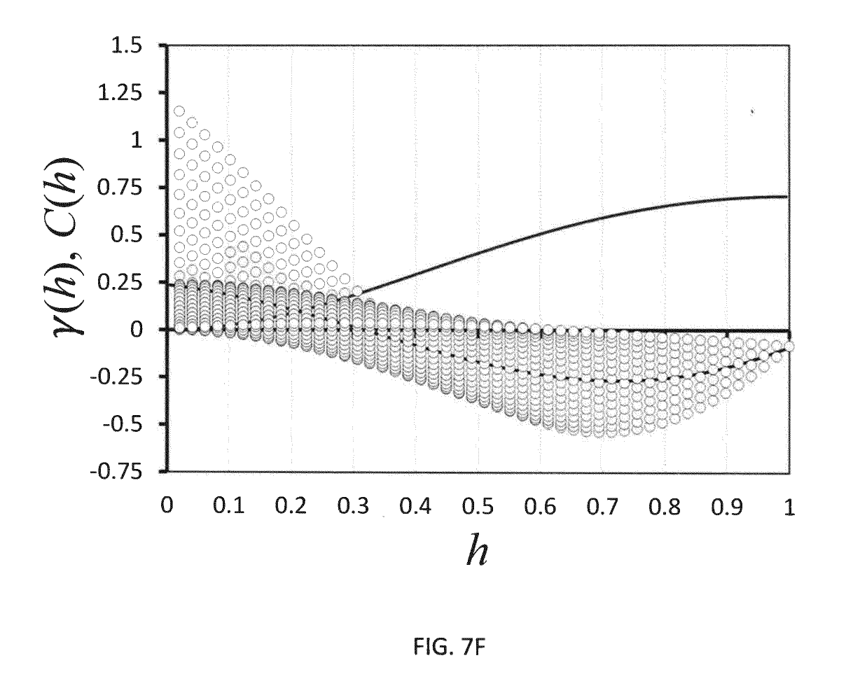

A simple, hypothetical response surface is utilized to show how the variogram γ(h) and covariogram C(h) of a response surface can be derived from samples of points on the response surface. FIG. 7A shows a one-factor response surface 700 with 10 randomly sampled points. FIGS. 7B and 7C show how the individual samples of the response surface are mapped (as pairs of samples) onto the variogram/covariogram space. As shown, the 10 sampled points result in 45 pairs of points with a wide range of h values (from 0.02 to 0.93).

As a more comprehensive example, FIG. 7D shows 50 regularly-spaced points sampled from the response surface 700, which result in a total of 1,225 pairs mapped onto FIGS. 7E-7F. Averaging the clouds of points (in the vertical direction for each h value) on the plots yields the variogram/covariogram. The number of pairwise combinations from a given set of k sampled points is k!/2!(k−2)!=k(k−1)/2. It is important to note that the 5-fold increase in the number of sampled points (from 10 to 50) results in a 27-fold increase in the number of pairs.

Note also that the covariogram C(h) tends towards the variance V[y] in the limit as the pairwise distance h approaches zero (i.e., C(h)→V[y] when h→0).

### Variogram Relation to Sensitivity

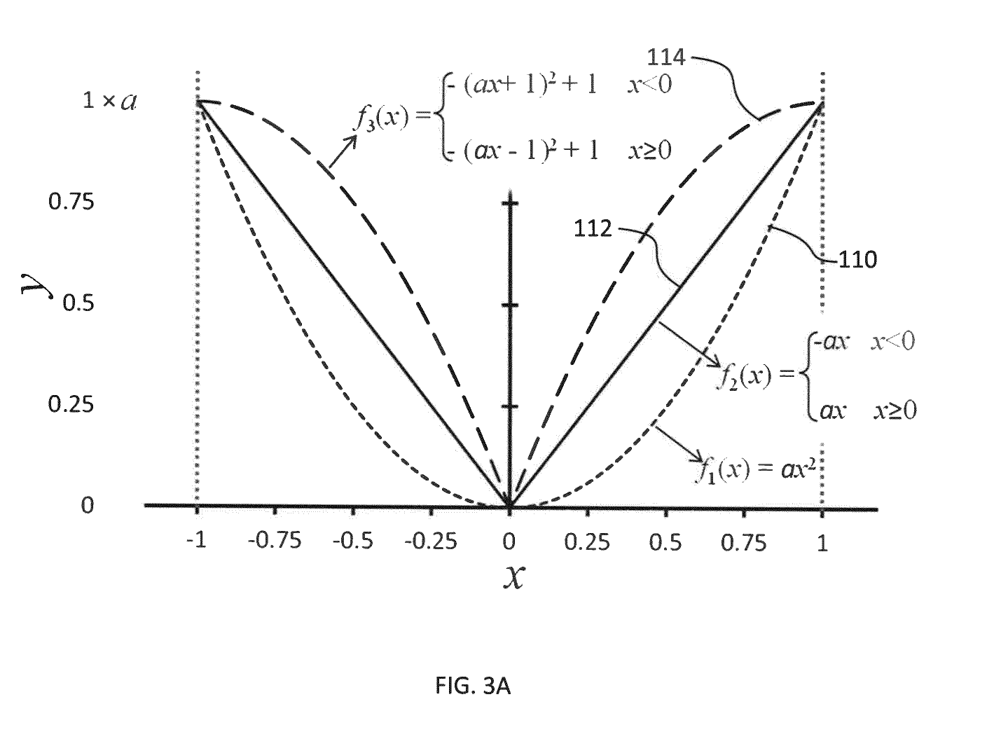

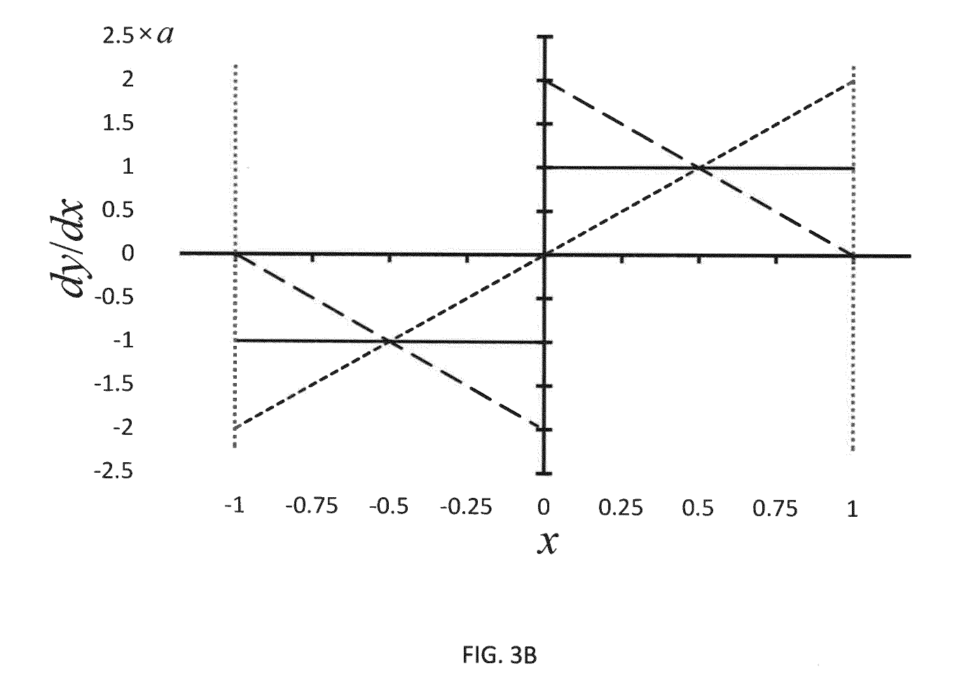

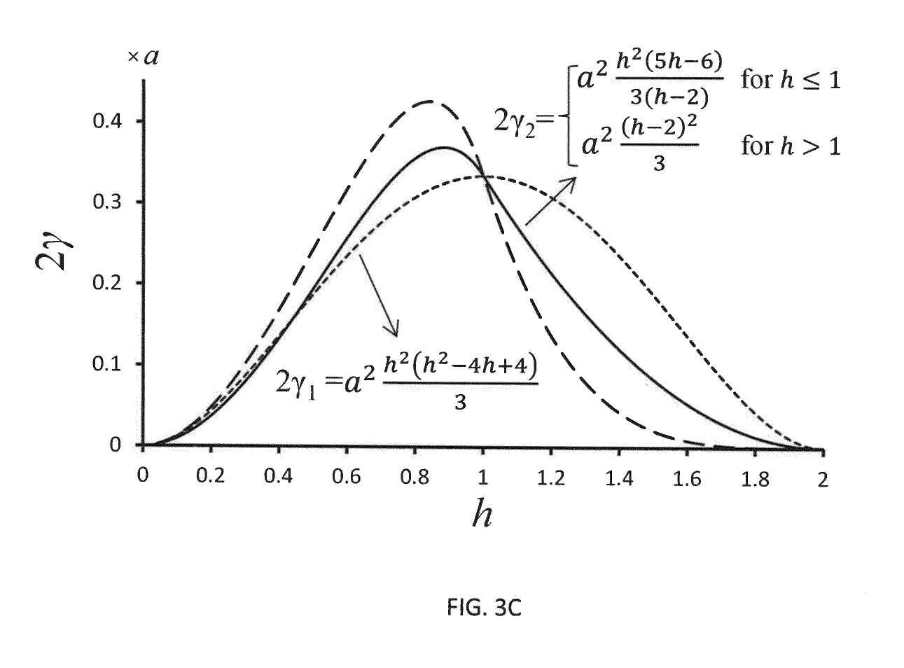

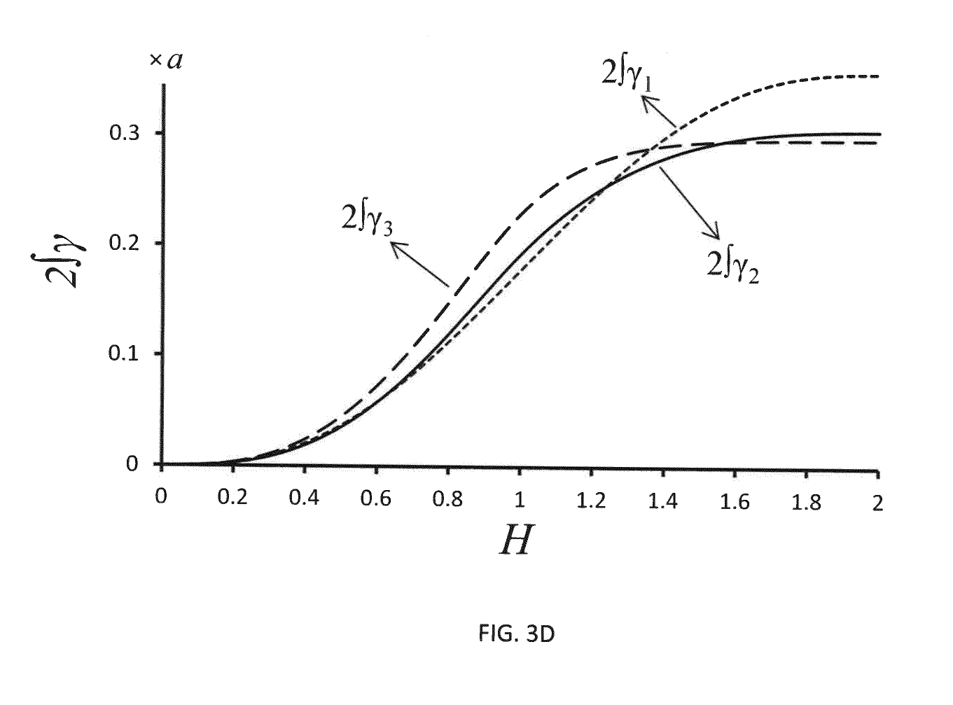

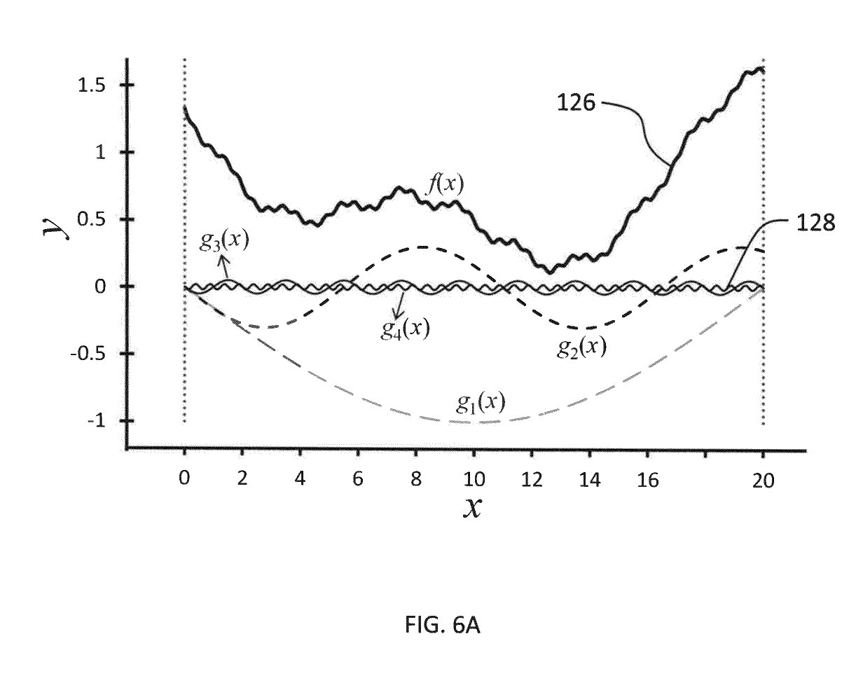

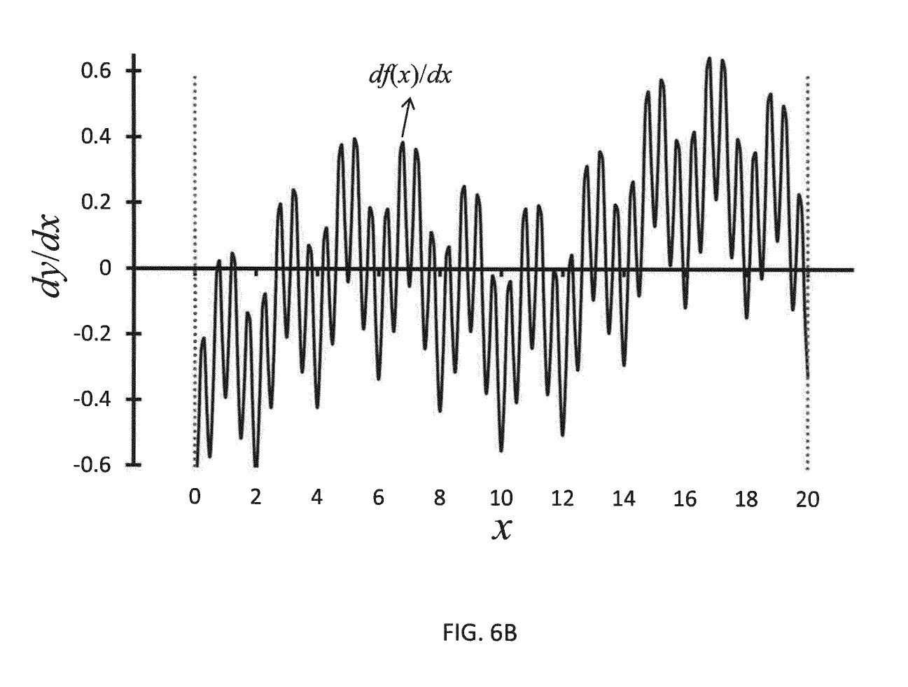

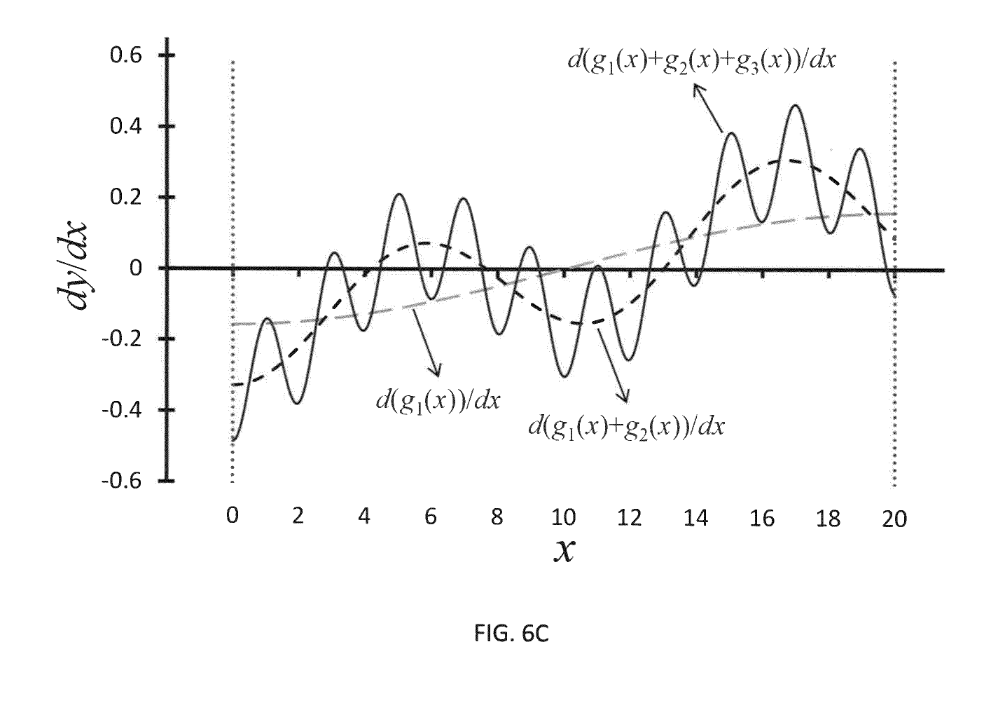

Returning to FIGS. 3A-6A, the VARS concepts of ‘direction’ and ‘scale’ is demonstrated. A higher value of γ(hᵢ) for any given hᵢ, indicates a higher ‘rate of variability’ of the underlying response surface in the direction of the i^{th} factor, at the scale represented by that hᵢ value. This rate of variability at a particular scale in the problem domain represents the ‘scale-dependent sensitivity’ of the response surface to the corresponding factor. Because variograms are defined over the full range of scales, they provide a spectrum of information about the sensitivity of the model response to the factor of interest.

The benchmark Sobol approach, described previously, may be represented by the variance of the response surface, V(y), and the Morris approach, described previously, may be represented by the averages of absolute and squared local sensitivities across the factor range,

$$E ( \vert \frac{d y}{d x} \vert ) and E ( {( \frac{d y}{d x} )}^{2} ) .$$

In these examples, derivatives are computed analytically, whereas in real-world case studies the derivatives

$$\frac{d y}{d x}$$

are usually estimated numerically by

$$\frac{Δ y}{Δ x} ,$$

where step size Δx in the factor space is analogous to h in the VARS approach.

FIG. 3 presents three uni-modal functions 110, 112, 114 (each having a single unique minimum) of the kind commonly shown in optimization textbooks. For functions f₁ 110 and f₃ 114, the overall variance

$$V ( y ) = \frac{4 {a}^{2}}{45} ,$$

and their probability density functions (PDFs) are mirror images of each other. Meanwhile for function f₂112, the overall variance

$$V ( y ) = \frac{{a}^{2}}{12} .$$

In addition,

$$E ( \vert \frac{d y}{d x} \vert ) = a$$

for all three functions,

$$E ( {( \frac{d y}{d x} )}^{2} ) = \frac{4 {a}^{2}}{3}$$

for f₁ 110 and f₃ 114, and

$$E ( {( \frac{d y}{d x} )}^{2} ) = {a}^{2}$$

for f₂ 112. According to these metrics, one may conclude that f₁ 110 and f₃ 114 are equally sensitive and slightly more sensitive than f₂ 112.

However, the three functions 110, 112, 114 have significantly different variograms (FIG. 3C). Remembering that γ(h) is a measure of ‘scale-dependent sensitivity’, we see that function F₃ 114 presents higher values of γ(h) for any h in the range of zero to one (half of the factor range), indicating it to be the most sensitive across all scales smaller than one. Meanwhile, f₁ 110 is slightly more sensitive than f₂ 112 on the scale range zero to 0.4, while f₂ 112 is more sensitive on the scale range 0.4 to 1. For values of h>1, f₁ 110 and f₃ 114 show the largest and the smallest sensitivities, respectively.

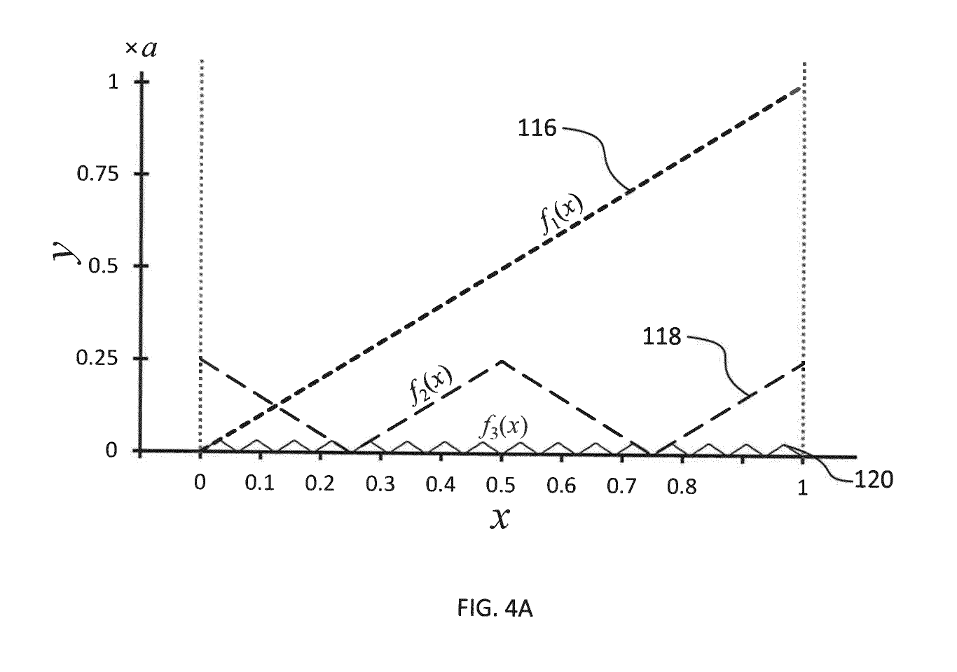

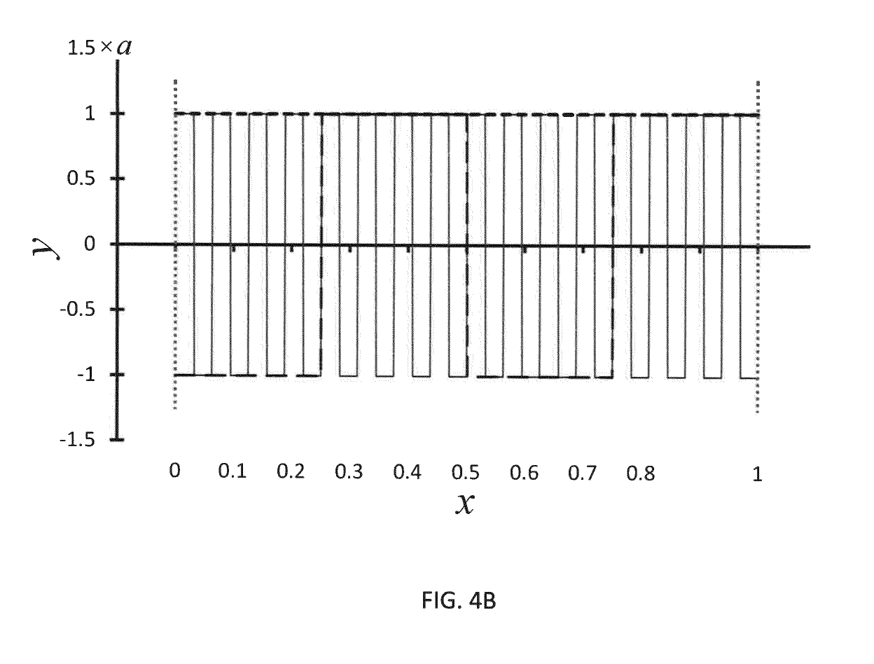

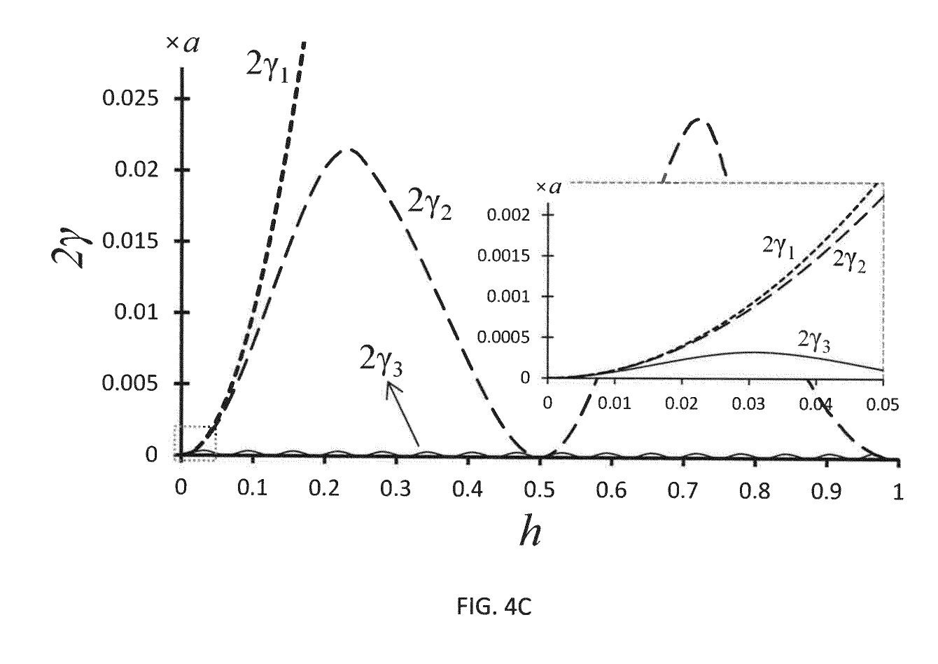

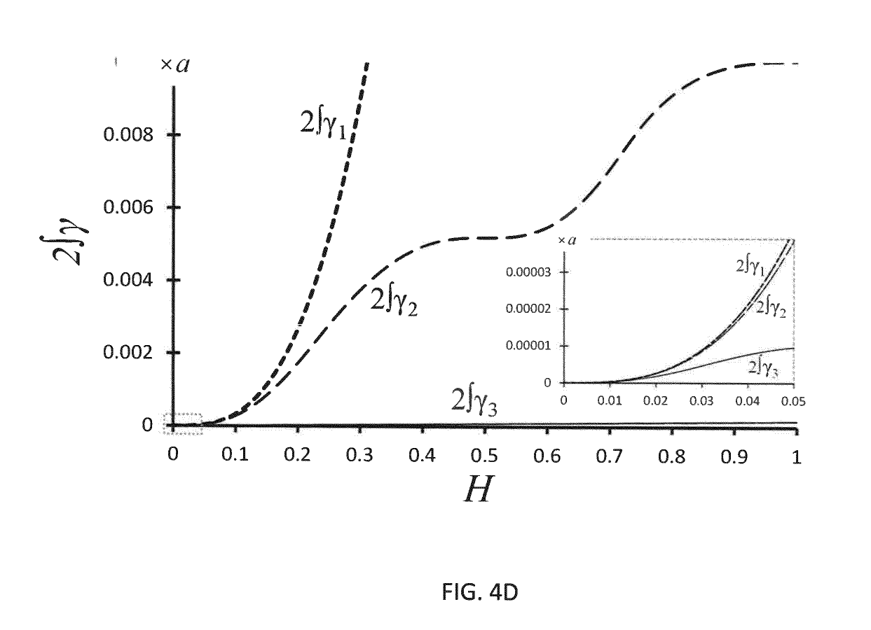

FIG. 4A presents three functions 116, 118, 120 that vary over radically different output ranges, while having constant and identical absolute values of the local sensitivities across the factor range (except at singular points where the derivatives change sign). All three cases have average absolute local sensitivity=a (see FIG. 4B), but significantly different response surfaces (see FIG. 4A). An intuitive interpretation is that f₁ 116 represents the situation with highest sensitivity of the response y to variations in factor x, because changes in x control a larger range of the output. However, in some situations, periodicities (multi-modalities) in the response surface may be very important in evaluating the impact of a factor. From the perspective of model calibration, the function f₂ 118 (characterized by two distinct regions of attraction) might be deemed quite ‘sensitive’ to x. Meanwhile f₃ is characterized by significant periodicity and has the same average absolute local sensitivity as the other two functions, but may simply represent an insensitive but non-smooth (noisy) model response, possibly due to numerical artefacts.

The values of overall variance V(γ) are

$$\frac{{a}^{2}}{{12}^{′}} \frac{{a}^{2}}{{192}^{′}} and \frac{{a}^{2}}{12288}$$

respectively for f₁ 116, f₂ 118, and f₃ 120, whereas,

$$E ( \vert \frac{d y}{d x} \vert ) a and E ( {( \frac{d y}{d x} )}^{2} ) = {a}^{2}$$

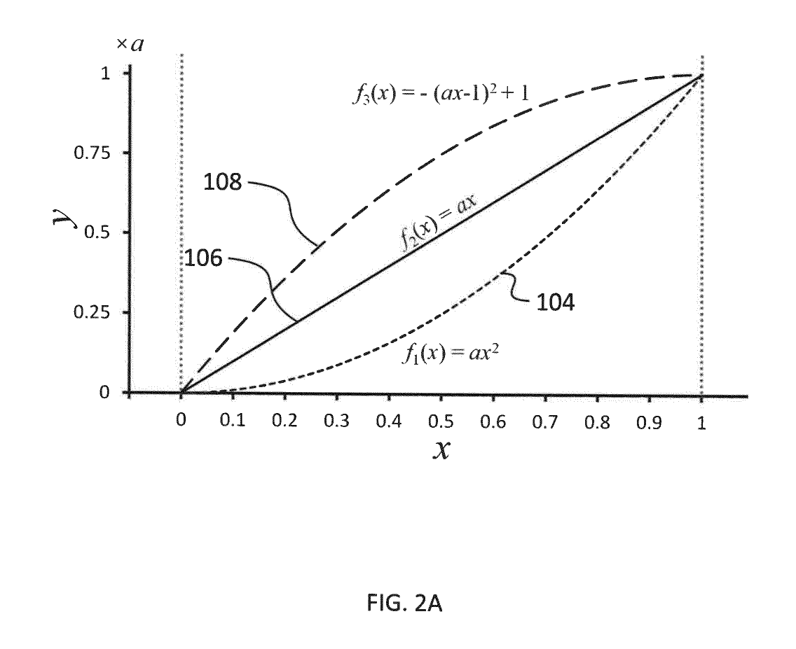

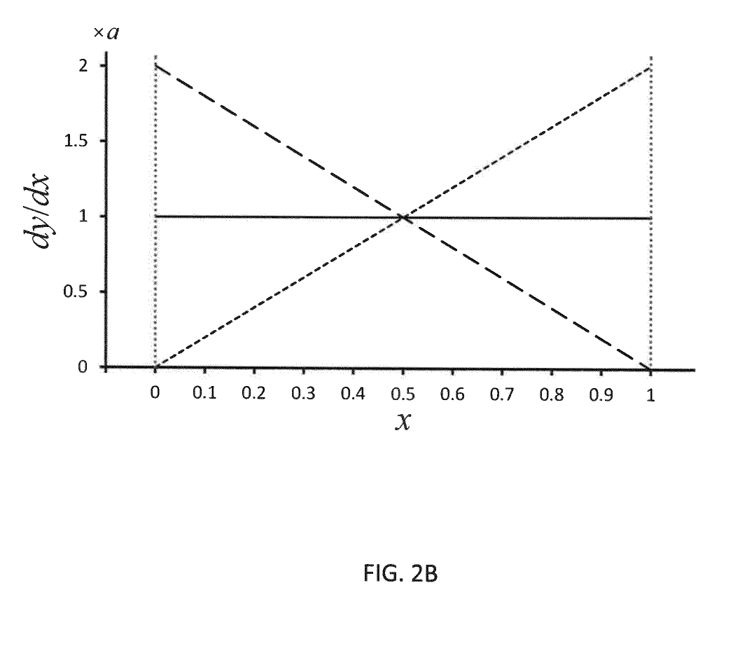

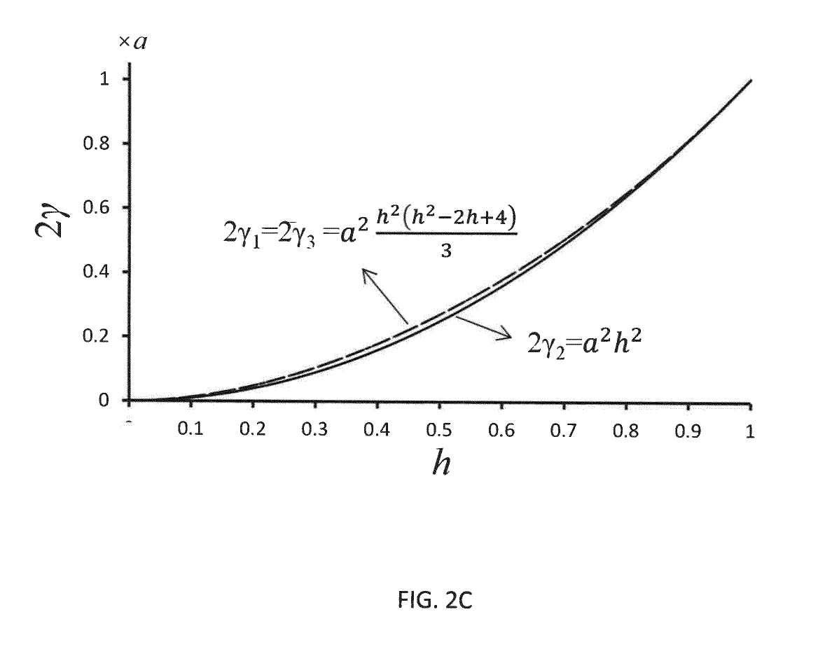

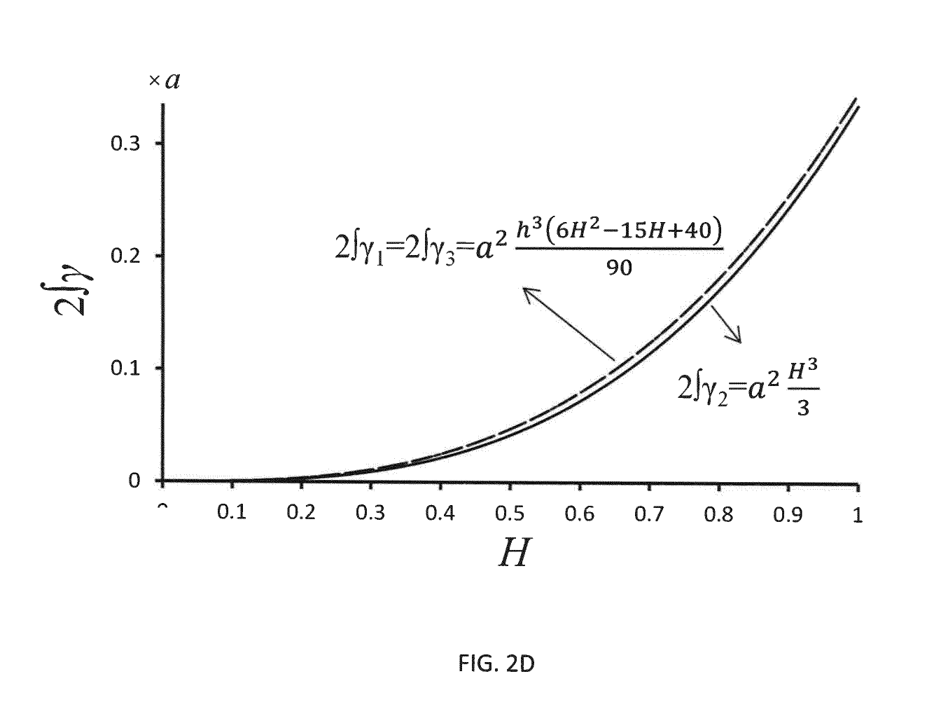

for all the three functions. Based on the Sobol approach, one would assess f₁ 116 to be 16 and 1026 times more sensitive to factor x than f₂ 118 and f₃ 120, while the Morris approach would deem the three functions to be equally sensitive. A comparison of the variograms (FIG. 2C) reveals these functions to be quite different. For h values smaller than 0.01 (very small scale), the three variograms indicate almost equal sensitivity, however, for larger scales, the variogram approach agrees clearly with the Sobol approach that f₁ 116 is the most sensitive. Further, the variograms of f₂ 118 and f₃ 120 display periodicity reflecting the multi-modal structures of their underlying response surfaces. Finally, the variogram of f₃ 120 shows very low sensitivity across all scales, indicating robustness of the VARS approach against noise/roughness in the underlying response surface.

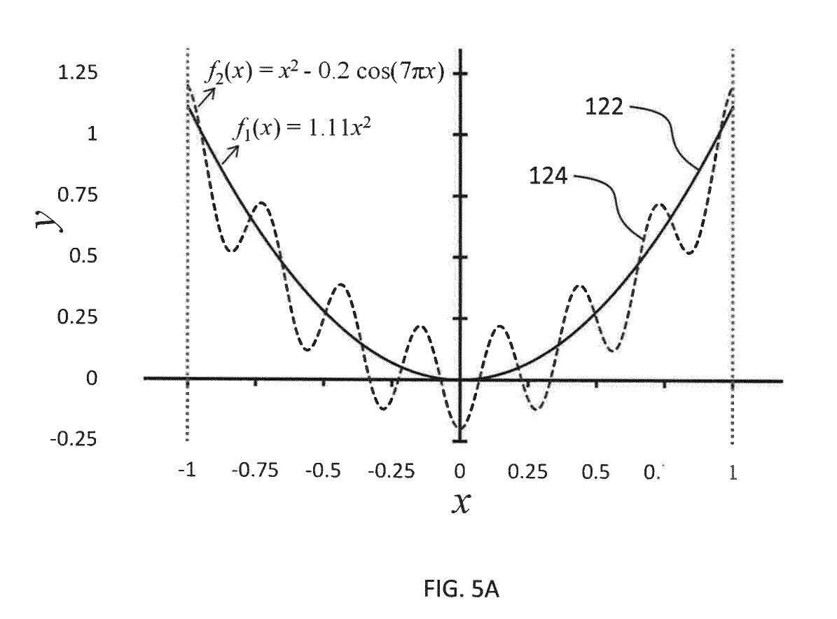

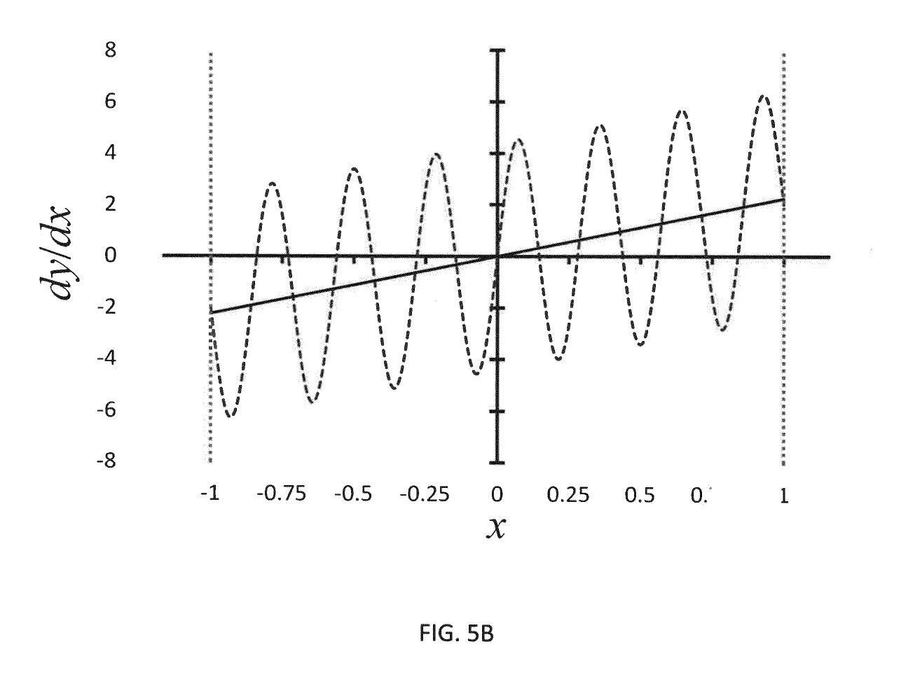

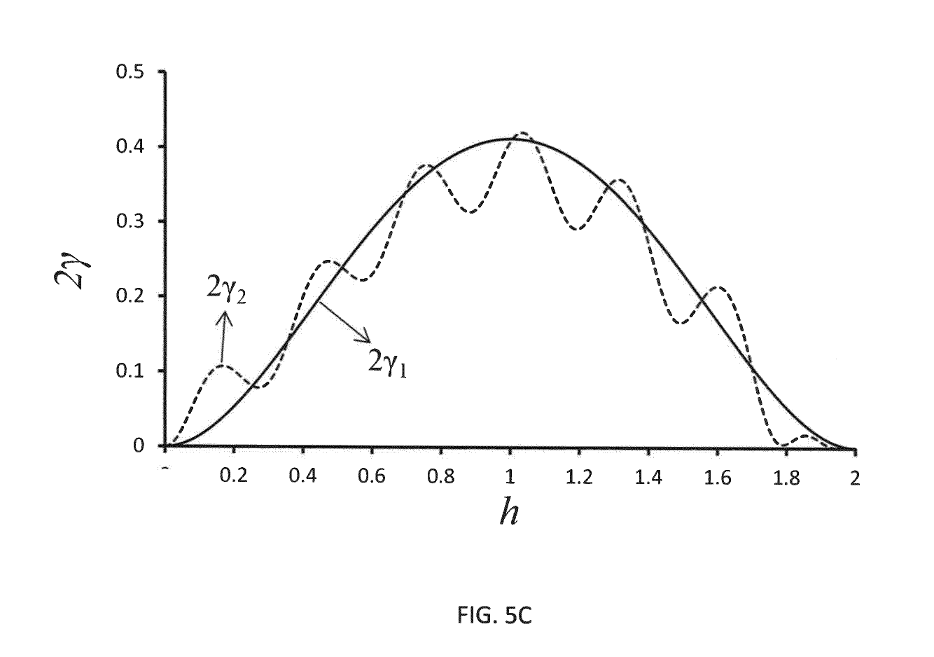

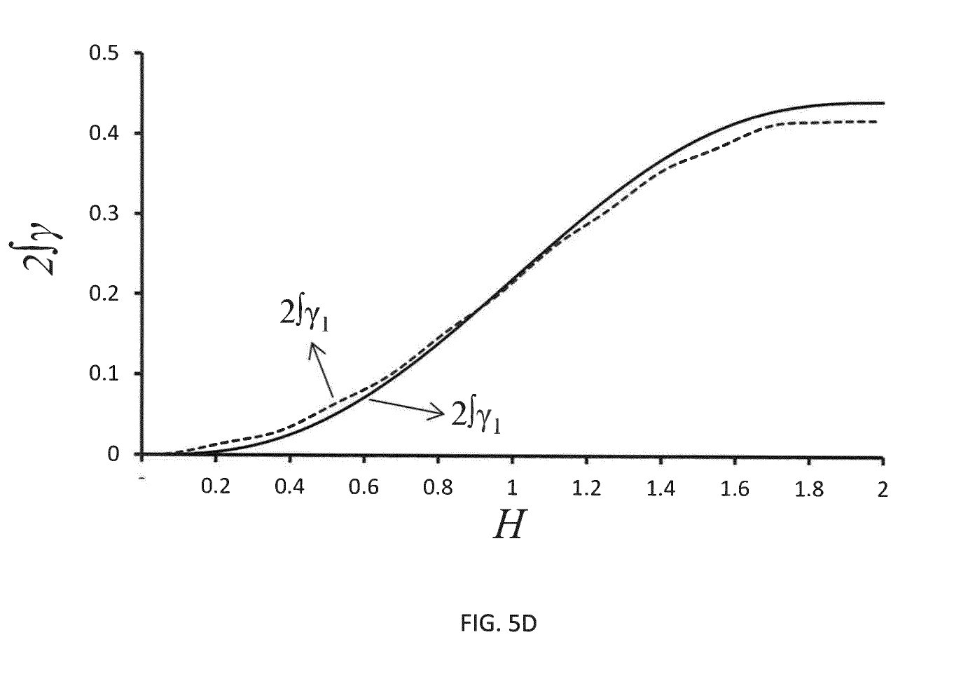

FIG. 5A presents two functions 122, 124 having the same average local sensitivity=0. Despite having very different response surfaces, they have an identical overall variance V(y)=0.11, which runs counter to our intuitive notion of sensitivity. This happens because the variance measures overall variability of the response but is not sensitive to the structure of that response—i.e., how the values of the response surface are organized in the factor space. Consequently, Sobol type variance-based methods are unable to take into account important structural information such as multi-modality. In contrast, the Morris-based measures can differentiate between the two functions. The values of

$$E ( \vert \frac{d y}{d x} \vert )$$

for f₁ and f₂ are 1.11 and 3.01, and the corresponding values of

$$E ( {( \frac{d y}{d x} )}^{2} )$$

are 1.64 and 11.80.

This example illustrates how a variogram conveys information about the structure of a response surface (see FIG. 5C). The variogram of the multimodal function f₂ 124 indicates significantly larger sensitivity for h on range of zero to about 0.2. For larger scales, the variogram of f₂ 124 shows periodicity caused by the multi-modality of the underlying response surface. At large scales (where the response surface structure becomes less important), the variograms indicates on average similar sensitivity of f₂ 124 and f₁ 122.

Note that in VARS, as in any variogram analysis, the maximum meaningful range of h is one half of the factor range, because for larger h values (h>50% of the factor range), a portion of the factor range will be excluded in the calculation of γ(h). For example, when h is 50% of the factor range, in all possible pairs of points (x^{A} and x^{B}), x^{A} is taken from one half and x^{B} is taken from the other half. When h is 75% of the factor range, in all possible pairs of points (x^{A} and x^{B}), x^{A} is taken from the range [0%-25%] and x^{B} is taken from the range [75%-100%], and therefore, no points will be taken from the range [25%-75%].

### Variogram Integration—a Comprehensive Metric of ‘Global’ Sensitivity

FIGS. 2A-5D showed that the variogram of a response surface provides a sort of ‘spectral’ representation of sensitivity across the range of possible scales. For a model with n factors, a directional variogram can be constructed for each factor so that the relative sensitivity of the model response to each factor can be evaluated at any scale of interest. Accordingly, the value of γ(hᵢ) at very small values of hᵢ (say e.g., hᵢ≦1% of the factor range) represents the average small-scale (local) sensitivity of the model response to factor i, while at large values of hᵢ (say e.g., hᵢ=25-50% of the factor range), it represents the average larger-scale sensitivity.

Except for the special case of linear models, there may not exist a single particular scale that provides an accurate assessment of sensitivity. This warrants the development of SA metrics that encompass sensitivity information over a range of scales. In VARS, such metrics of factor sensitivity can be obtained by integrating the directional variograms over some scale range of interest (equivalent to computing the cumulative area under the variogram). Given a scale range varying from zero to H, for the i^{th} factor, the “Integrated Variogram”, Γ(Hᵢ), is computed as:

Γ(Hᵢ)=∫₀^{H}^{ᵢ}γ(hᵢ)dhᵢ (Eq-15)

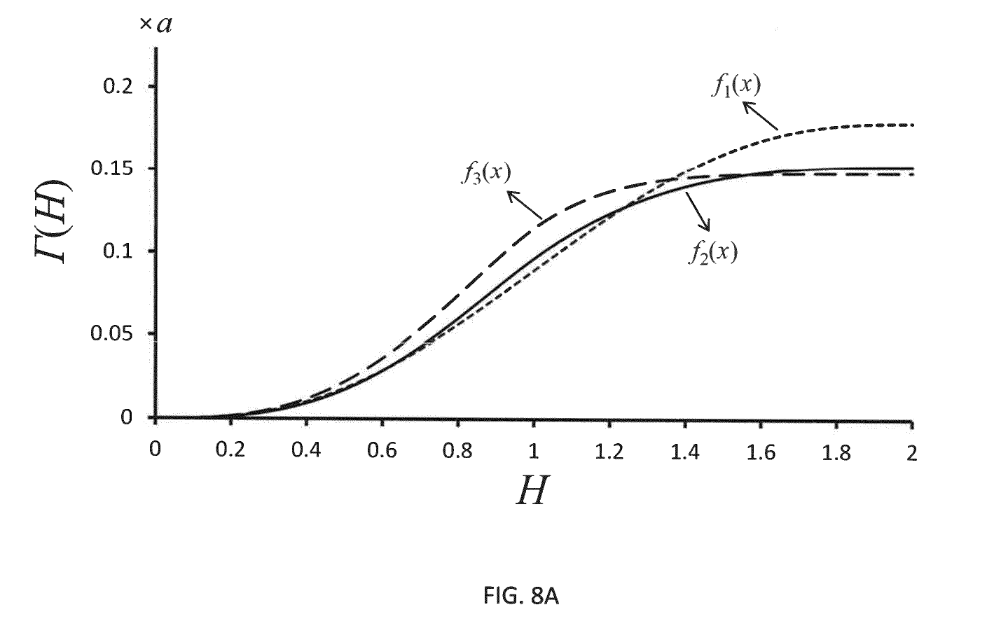

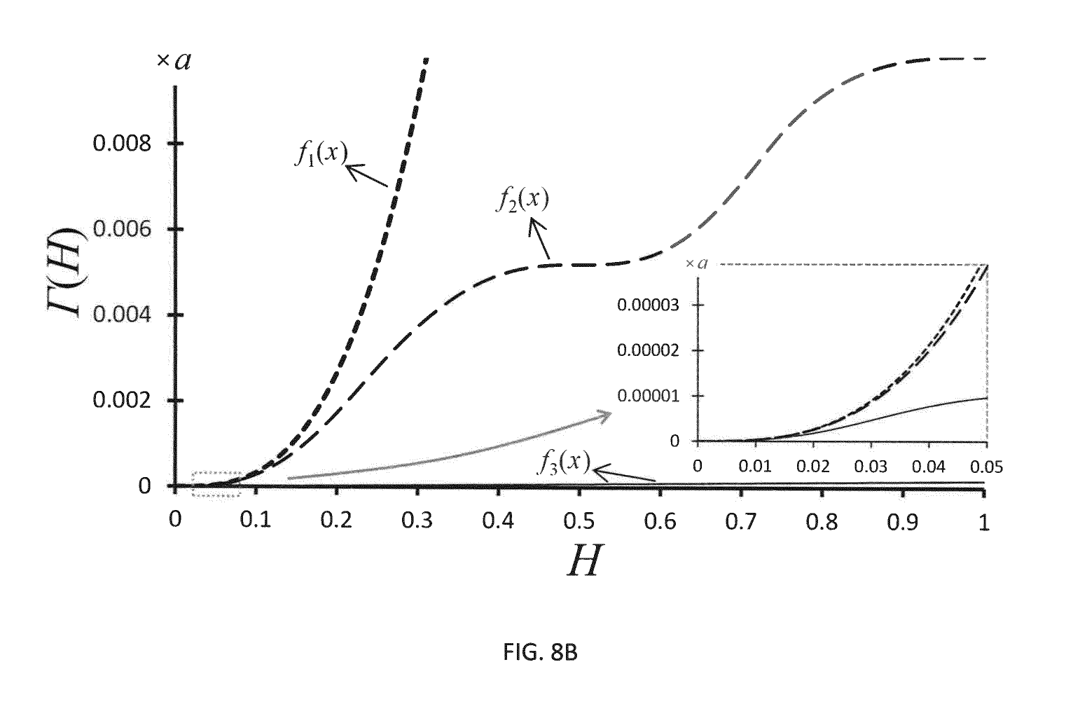

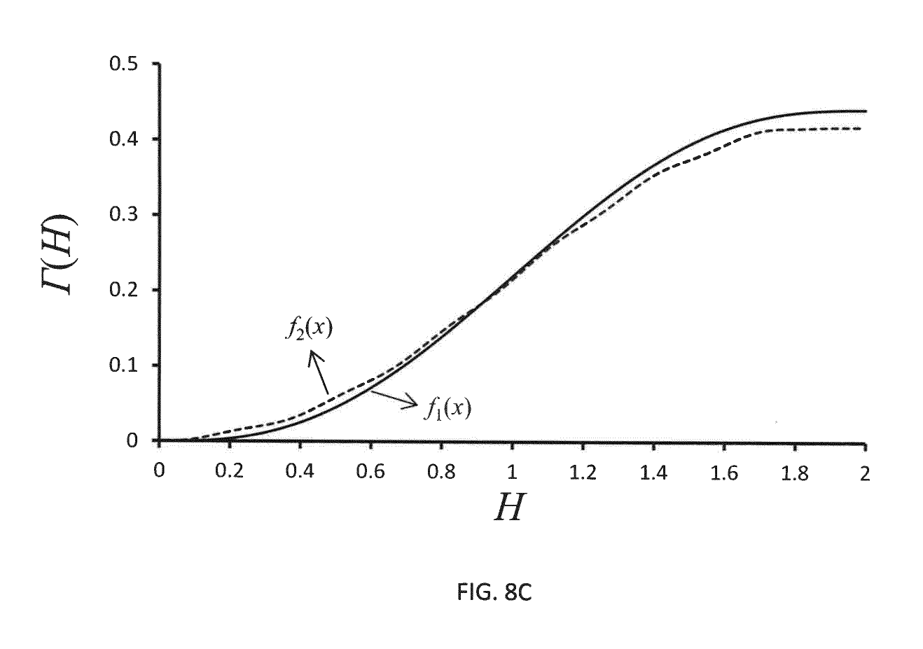

FIGS. 8A-8C illustrate this integrated variogram concept for the functions in the previous examples of FIGS. 3A through 5D, by plotting Γ(H) versus H over the full factor range; although Γ(H) is shown over the full range for the sake of completeness, Γ(Hᵢ) can be meaningfully interpreted only when H is smaller than one half of the factor range as described previously. For the example of FIG. 3D shown in FIG. 8A, f₃ 114 has a consistently larger Γ(H) than f₁ 110 and f₂ 112 over the H range of zero to 50% of the factor range, while f₁ 110 has a slightly larger Γ(H) than f₂112 when H<25%, and conversely when 25%<H<50%. For the example of FIG. 4D shown in FIG. 8B, all three functions have similar Γ(H) values at very small H values (0-2% of the factor range), but sensitivity of the functions can be ranked as f₁ 116>f₂ 118>f₃ 120 for any larger H value. For the example of FIG. 5D shown in FIG. 8C, the value of Γ(H) is larger for f₂ 122 than f₁ 124 for 0<H<0.9, and the values become similar near H=1.

These examples show that the function Γ(H), representing the “Integrated Variogram Across a Range of Scales” (IVARS) can provide a meaningful measure of the sensitivity of a model response to its factors. In each of the examples shown above, if the different functions are thought of as the responses to different (non-interacting) factors of a model, IVARS-based sensitivity measures can be used to rank the factors in terms of their influence. For example, the sensitivity could be computed for H equal to 10% (IVARS10), 30% (IVARS30), and 50% (IVARS50) of the factor range.

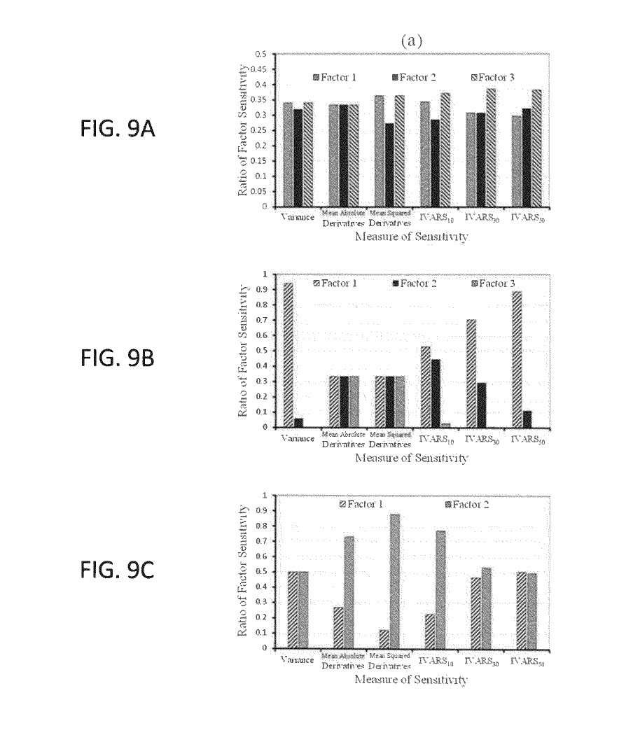

FIGS. 9A-9C show a comparison between the IVARS10, IVARS30, and IVARS50 metrics of sensitivity and the Sobol and Morris based benchmarks discussed previously. Each subplot shows the ratios of factor sensitivity (which are the values of each metric divided by the summed values of that metric over all of the factors) for the examples of FIGS. 3A-3D, 4A-4D, and 5A-5D. In the example of FIGS. 3A-3D, according to all three IVARS10, IVARS30, and IVARS50 metrics, Factor 3 is the most sensitive (differing from the assessment provided by the benchmarks). Factor 1 is more sensitive than factor 2 according to IVARS10, almost equally sensitive according to IVARS30, and less sensitive according to IVARS50. In the example of FIGS. 4A-4D, the sensitivity ordering is Factor 1>Factor 2>Factor 3 according to all the three new metrics (agreeing with the Sobol assessment). In the example of FIGS. 5A-5D, Factor 1 is significantly less sensitive than Factor 2 according to IVARS10 and equally sensitive according to IVARS50 (agreeing with the Morris benchmarks at shorter scales and the Sobol benchmark at larger scales).

### Representation of Response Surface Multi-Modality in Variograms

While the VARS characterization of the response surface corresponds to the Morris approach at small scales and the Sobol approach at large scales, it has the important property that it characterizes the structural organization of the response surface and can, therefore, reveal a range of multi-modality (or periodicity) features that may exist, from very small-scale fluctuations (e.g., noise or roughness) to large-scale (dominant) modes. Modes (non-monotonicity) in a response surface will result in negative correlations (covariance structures) and be revealed as periodicities in the variogram. This behavior is present in the three conceptual examples at different scales. In multi-dimensional (multi-factor) problems, γ_{x*}_{_{˜i}}(hᵢ), the directional variogram for factor i when all other factors are fixed at x*_{˜i}, represents the multi-modalities in that cross section of the factor space (defined by x*_{˜i}). Therefore, γ(h₁), which is E[γₓ_{_{˜i}}(hᵢ)], averages such features for factor i across the factor space and reveals the dominant ones. In spatial statistics, this behavior is known as the ‘hole effect’.

### Practical (Numerical) Implementation of the VARS Approach

As with the Morris and Sobol methods, for practical problems the sensitivity metrics are estimated via sampling of the response surface. A ‘star-based’ strategy is presented that is designed to make available the full range of sensitivity-related information provided by the VARS approach; other strategies are of course possible. Without loss of generality, all factors are scaled to vary on the range zero to one. The steps are as follows:

Select Resolution: Select Δh, which represents a ‘smallest’ value for h. This enables numerical computation of the variogram at the following h values: 0, Δh, 2Δh, 3Δh, etc.

Generate Star Centers: Randomly choose m points, located across the factor space via Latin Hypercube Sampling, and evaluate the model response at each of these ‘star centers’. Denote their locations using xⱼ⁺={x_{j,1}⁺, . . . x_{j,i}⁺, . . . , x_{j,n}⁺} where j=1, . . . , m.

Generate Cross Sections: For each star center, generate a cross section of equally spaced points Δh apart along each of the n dimensions in the factor space, including and passing through that star center xⱼ⁺ and evaluate the model response at each new point. The i^{th} cross section, where i=1, . . . , n, is obtained by fixing x_{˜i}=x_{j,˜i}⁺ and varying xᵢ. This results in (1/Δh)−1 new points for each cross section, and a total of n((1/Δh)−1) new points for each star center. The set of points generated around a star center (including the star center) is called a ‘star’.

Extract Pairs: For each dimension, extract all the pairs of points with h values of Δh, 2Δh, 3Δh, and so on. In total, this results in m((1/Δh)−1) pairs with h=Δh, m((1/Δh)−2) with h=2Δh, m((1/Δh)−3) with h=3Δh, etc. for each dimension (using all of the stars).

For each of the sample pairs obtained, numerical estimates of following can be computed:
Directional variograms, γ(h₁), integrated variograms, Γ(H), and covariogram, C(hᵢ), where i=1, . . . , n.
Morris-based sensitivity measures across a range of scales (Δx=Δh, 2Δh, 3Δh, etc. where Δx is the step size for the numerical calculation of partial derivatives).
Directional variograms and covariograms for any cross sections, γ_{X}_{_{˜i}}(hᵢ) and Cₓ_{_{˜i}}(hᵢ).
The variance-based total-order effect using, referred to as “VARS-TO” (TO for Total Order).

The computational cost of this star-based sampling strategy (i.e., the total number of model runs) is m[n((1/Δh)−1)+1]. The strategy can be easily parallelized when computational time is limited.

### Bootstrapping

Bootstrapping can be performed in conjunction with the above sampling strategy to generate estimates of: (a) confidence intervals on the resulting sensitivity metrics; and (b) reliability of the inferred factor rankings.

Bootstrapping can performed by:
Randomly sample with replacement m of m star centers.
Calculate the sensitivity metrics and factor rankings using the cross sections associated with the m bootstrap-sampled star centers.
Repeat sampling and calculating a total of k times (where k is some large number, e.g., hundreds or thousands), and each time, store the resulting sensitivity metrics and factor rankings. These are deemed samples of the multi-variate distributions of the sensitivity metrics and factor rankings.
   Then, for each factor and each sensitivity metric:
Calculate confidence intervals (e.g., 90% intervals) from the associated marginal distribution.
Count the number of times (out of the total k times sampling with replacement) that the rank of that factor is the same as the original rank obtained (based on all star centers)—this ratio is deemed an estimate of the reliability of a factor ranking.

### EXAMPLES

Following are three examples having different characteristics that will be used to demonstrate the VARS approach and explain its different features.

### Example 1

### Six-Dimensional Response Surface without Interactions

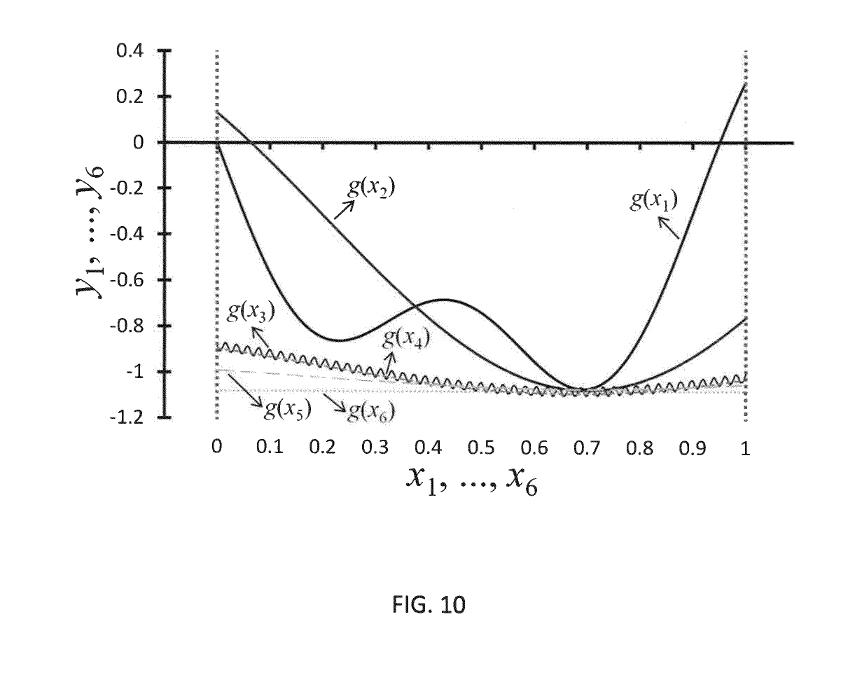

FIG. 10 illustrates a synthetic test function with six fully non-interacting factors. The function ƒ(·) is constructed as the sum of six one-factor functions, g₁(·) . . . , g₆(·), as follows:

y=ƒ(x₁, . . . ,x₆)=g₁(x₁)+g₂(x₂)+ . . . +g₆(x₆) (Eq-16)

where:

g₁(x₁)=−sin(πx₁)−0.3 sin(3.33πx₁) (Eq-16a)

g₂(x₂)=−0.76 sin(π(x₁−0.2))−0.315 (Eq-16b)

g₃(x₃)=−0.12 sin(1.05π(x₁−0.2))−0.02 sin(95.24πx₁)−0.96 (Eq-16c)

g₄(x₄)=−0.12 sin(1.05π(x₁−0.2))−0.96 (Eq-16d)

g₅(x₅)=−0.05 sin(π(x₁−0.2))−1.02 (Eq-16e)

g₆(x₆)=−1.08 (Eq-16f)

Intuitively, the sensitivity of the factors in Eq-16 may be ranked as follows: x₁>x₂>x₃>x₄>x₅>x₆. Comparing x₁ and x₂, the effect of x₁ is more complex (bi-modal), the slope along x₁ is generally larger, and also x₁ controls a larger range of variation in y. The effect of x₃ is effectively similar to the effect of x₄, augmented by some degree of roughness (high frequency and low amplitude noise). Such roughness is common in the response surfaces of EESMs. Further, the response surface formed is absolutely insensitive to x₆.

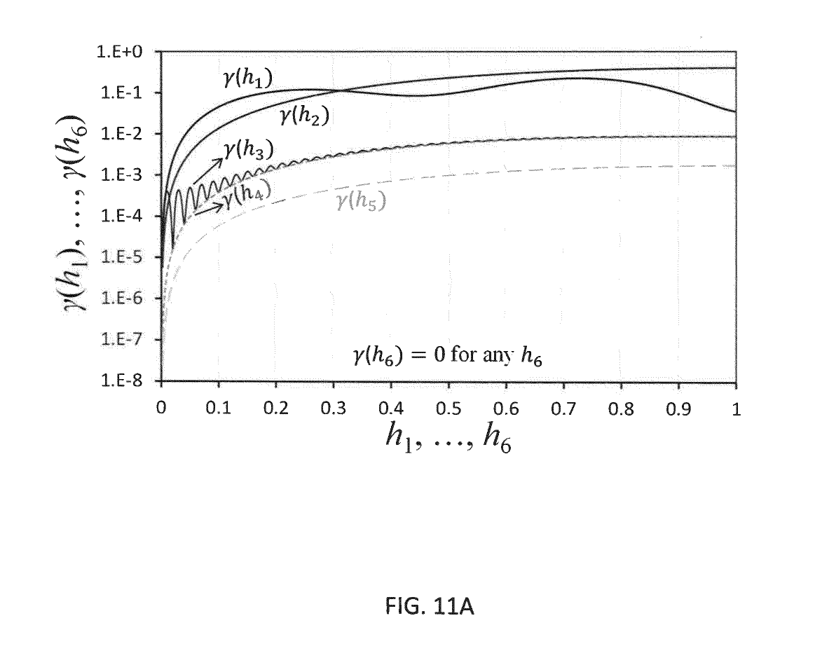

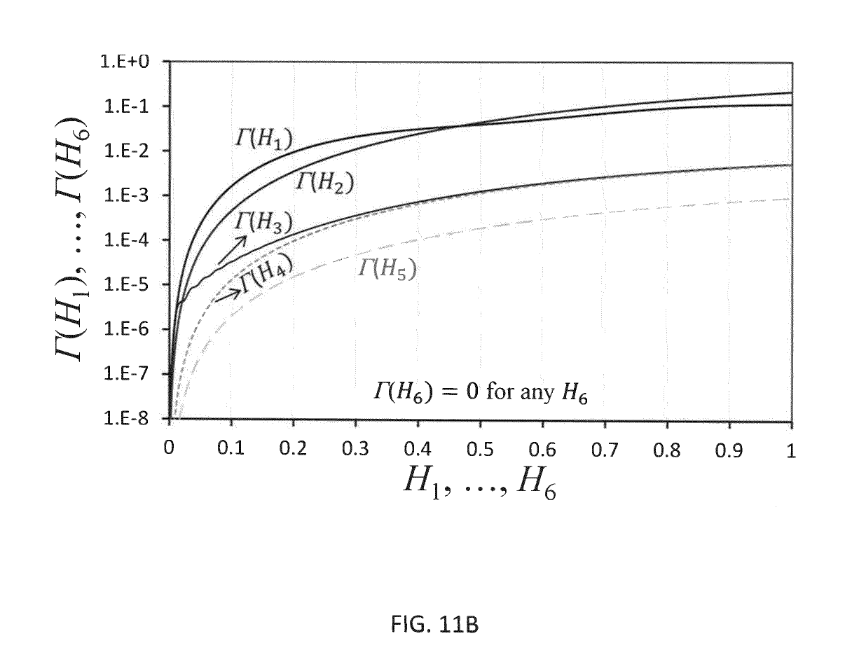

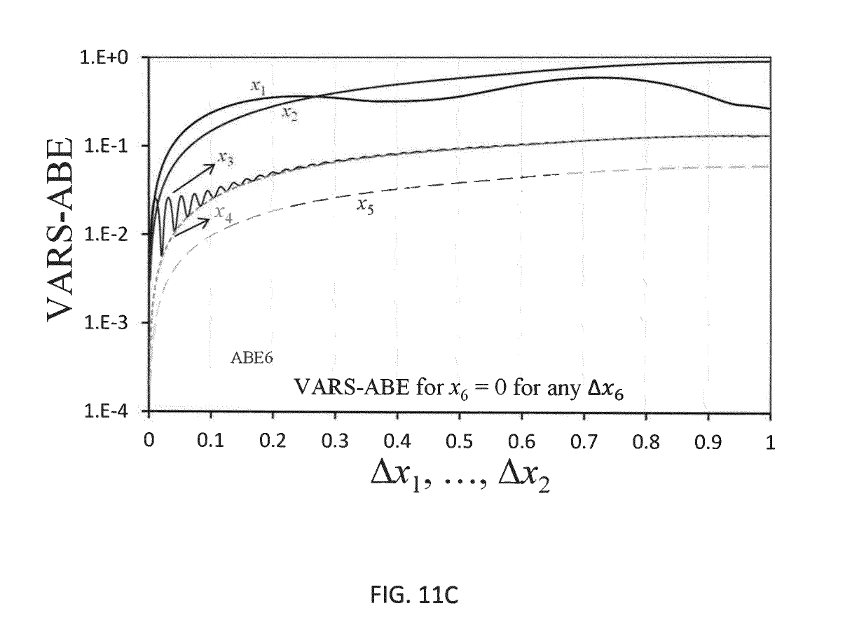

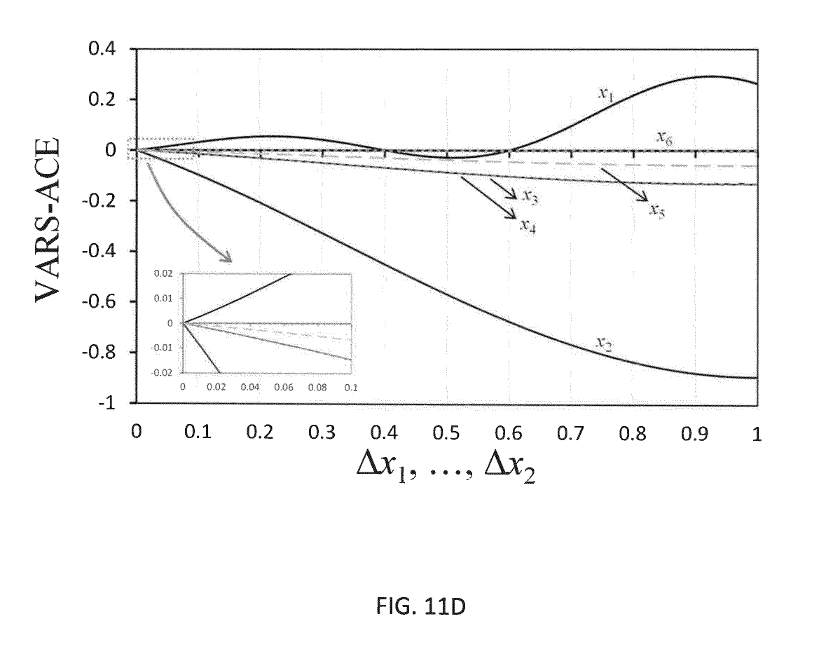

FIGS. 11A-11B present the directional variograms and their integrations respectively, over the full range of factor scales represented by hᵢ, =1, . . . , 6. As shown, γ(h₁)>γ(h₂) for a range of scales smaller than 0.312, and after this point γ(h₁)<γ(h₂). Also, for very small scales (e.g., smaller than 0.01), γ(h₃) is larger or as large as γ(h₁) and γ(h₂). For larger scales, γ(h₃) falls behind and gradually converges to γ(h₄). When h₃ and h₄ are exactly equal to an integer multiple of the period of the roughness term in g(x₃), i.e., 0.021, we get γ(h₃)=γ(h₄). This demonstrates the ‘sensitivity’ of the results of a conventional sensitivity analysis procedure to the choice of scale.

The integrated variograms, Γ(H₁), . . . , Γ(H₆), shown in FIG. 11B provide a way of characterizing such sensitivity information over a range of scales, thereby providing a broader view of sensitivity. Because γ(h₄)>γ(h₅) over the full range of scales we get Γ(H₄)>Γ(H₅) everywhere, indicating that the response surface is more sensitive to x₄ than x₅, regardless of the choice of scale.

FIGS. 11C-11D show the Morris-based mean absolute elementary effects (ABE) and mean actual elementary effects (ACE) of the six factors on the response surface, computed across the full range of scales via the VARS approach; they are referred to as VARS-ABE and VARS-ACE because they are computed as by-products of the VARS approach. These figures demonstrate how implementation of the Morris approach can be sensitive to scale. Note that VARS-ACE provides different assessments of relative factor sensitivity from VARS-ABE at different scales.

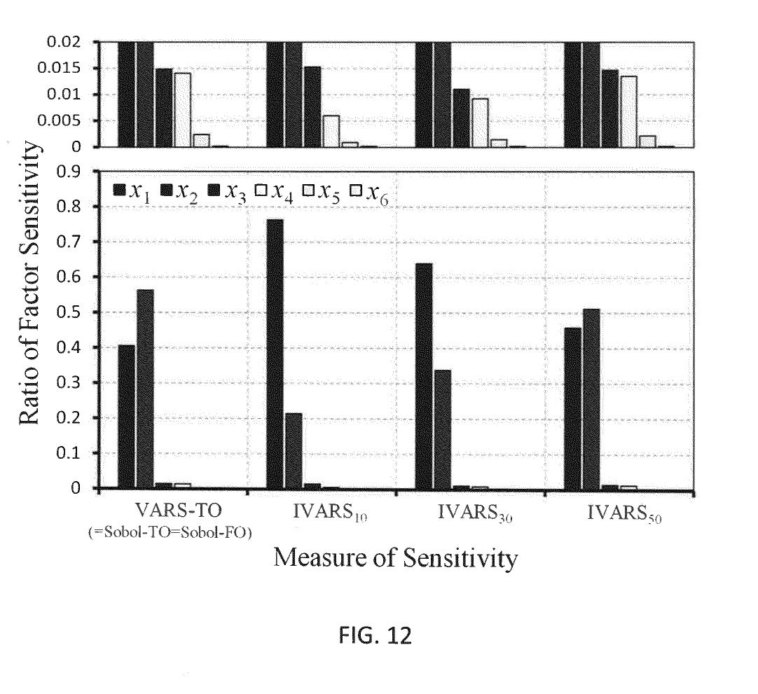

FIG. 12 compares the factor sensitivity ratios for four sets of sensitivity metrics obtained by the VARS approach. As there are no ‘interaction effects’ in this case study, the variance-based (Sobol) total-order sensitivity indices (denoted as VARS-TO or Sobol-TO) are equal to the first-order sensitivity indices (denoted as Sobol-FO). The results indicate that the Sobol approach evaluates factor x₂ as being “more sensitive” than factor x₁ (more accurately stated, this means that the sensitivity of the model ‘response’ to variations in factor x₂ is larger than its sensitivity to variations in factor x₁) which seems contrary to intuition. However, it does evaluate factor x₃ as being very marginally more sensitive than factor x₄, as the roughness term in g(x₃) only very slightly inflates the variance of the function.

In contrast, the proposed IVAR10, IVARS30, and IVARS50 sensitivity metrics correspond well with our intuitive understanding of sensitivity. For example, for smaller scales (represented by IVARS10), factor x₁ is deemed to be significantly more sensitive than factor x₂, and the sensitivity to factor x₃ is significantly greater than that to factor x₄. At medium scales (represented by IVAR30), the difference in sensitivity between factors x₁ and x₂ is reduced but still significant; while for factors x₃ and x₄ the difference in sensitivity is significantly reduced. At larger scales (represented by IVARS50), factor x, becomes slightly less sensitive than factor x₂, and the difference in sensitivities of factors x₃ and x₄ becomes marginal; these are consistent with the Sobol-TO (=VARS-TO) assessment of sensitivity.

The results of example 1 were obtained by the ‘star-based sampling’ numerical implementation of VARS using a very small Δh=0.002. Because there are no interactions between the factors in this example, only one randomly selected star point (m=1) was needed to conduct a complete VARS assessment, requiring a total of 2,995 function evaluations to generate results having very high precision. However, in practice such a small value for Δh is not necessary. To evaluate robustness of the VARS approach to sampling variability, 500 independent VARS trials with m=1, Δh=0.01 were conducted, and different initial random seeds (i.e., different star points)—a total of 595 function evaluations were required for each trial. The robustness is assessed by computing the ‘probability of failure’ (PF) in generating any of the SA products (i.e., IVARS10, IVARS30, IVARS50, and VARS-TO). Accordingly, PF represents the fractional number of trials (out of the total 500 trials) in which the factor ranking generated by the particular SA metric is not consistent with the true factor ranking computed by that metric. The resulting PF values for all of the VARS products were zero when Δh=0.01, indicating that VARS is extremely reliable.

A larger value Δh=0.1 requires only 55 functional evaluations for each trial. In this case, the probability of failure PF was obtained to be zero for IVARS30, IVARS50, and VARS-TO, but was found to be almost 50% (PF=0.5) for IVARS10. To explain this, note that Δh=0.1 is much larger than the characteristic length of the roughness existing in g₃(x₃), in this case the period of the noise term. Because we are not able to characterize (h₃) for h₃<0.1, and as such for H=0.1, we get an estimate for Γ(H₃) that is equal to Γ(H₄); therefore, IVARS10 is unable to differentiate between the factor sensitivities of x₃ and x₄. Accordingly, in the 500 trials, each factor has an almost equal chance of being determined to be very marginally more sensitive than the other. Let's define PF(xᵢ, xⱼ) as the probability of failure in correctly ranking factors xᵢ and xⱼ by a sensitivity measure. According to IVARS10, this results in PF(x₃, x₄)≈0.5, and PF(xᵢ, xⱼ)=0 for all other pairs of xᵢ and xⱼ.

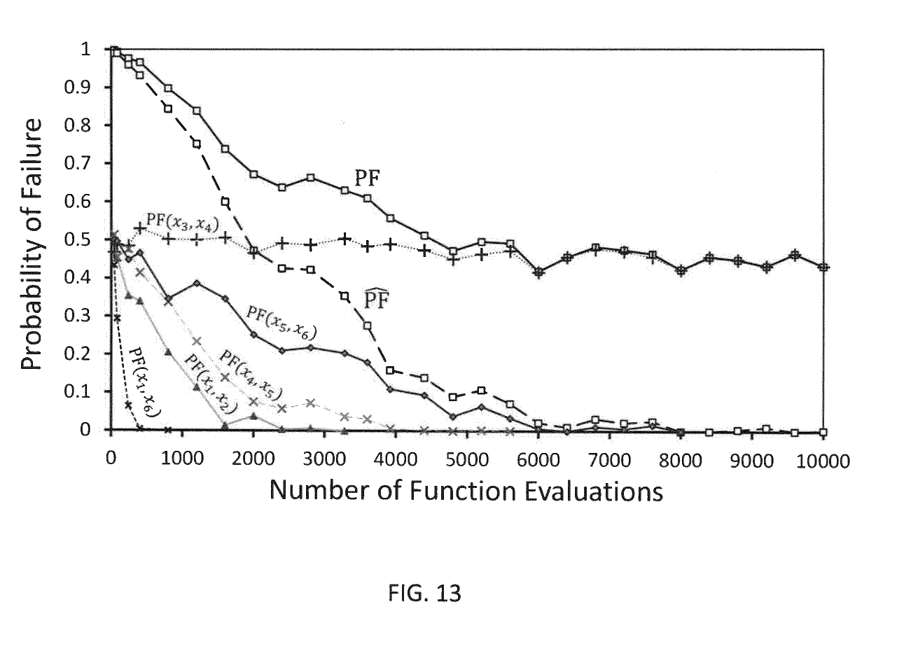

FIG. 13 illustrates the robustness and efficiency of the VARS methodology compared to a traditional Sobol-based sampling and implementation strategy for SA, referred to here as Sobol-TO. FIG. 13 shows the PF values for the Sobol-TO approach for different computational costs (numbers of function evaluations). The results show that PF(x₁, x₆) approaches zero after 400 function evaluations (for each random trial), indicating that to reliably differentiate a sensitive factor (i.e., x₁) from a fully insensitive factor (i.e., x₆) requires a relatively large number of function evaluations. In contrast, PF(x₆, x₆) approaches zero only after a significantly large number (˜6,000) of function evaluations. Also, the method was unable to reliably differentiate between factors x₃ and x₄, even within the maximum number of function evaluations used (PF(x₃, x₄)=0.5). The overall result is that PF remains around 0.5 for the large computational costs. If we ignore the distinction in ranking between factors x₃ and x₄ (equivalent to ignoring the effect of the noise), and call this [symbol] , we find that the probability of failure approaches zero after a computational cost of ˜6,000 function evaluations. Comparing these results with those for VARS reported above, it becomes clear that the VARS approach is significantly more efficient and robust in this case—an efficiency gain of more than two orders of magnitude (6,000/55).

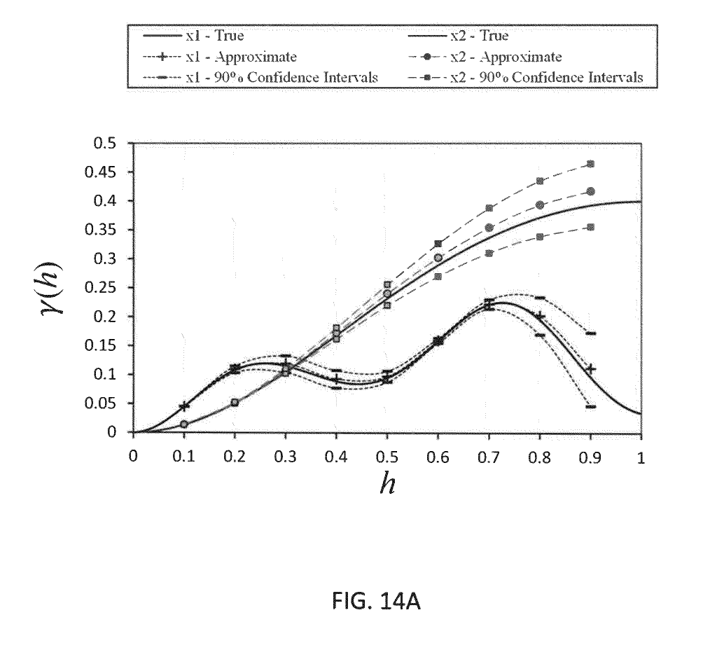

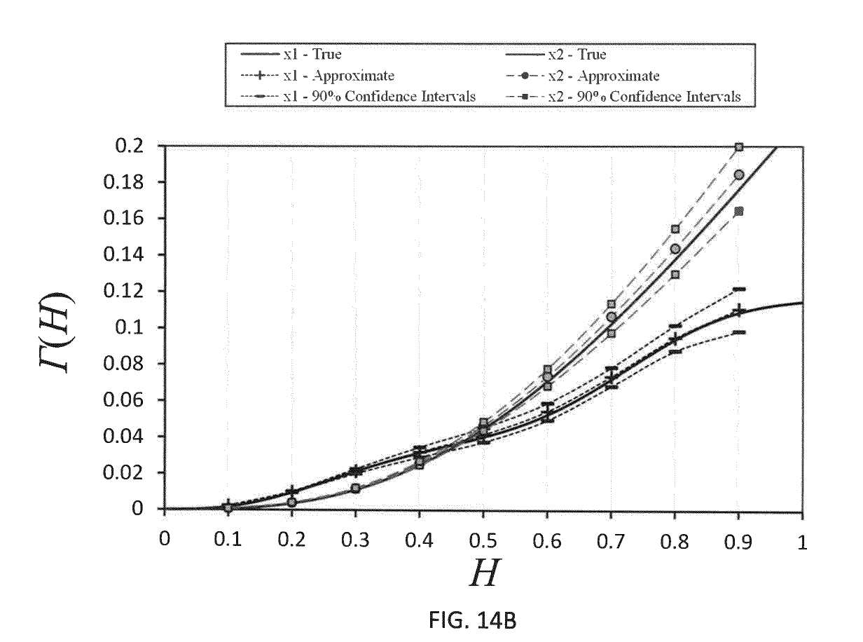

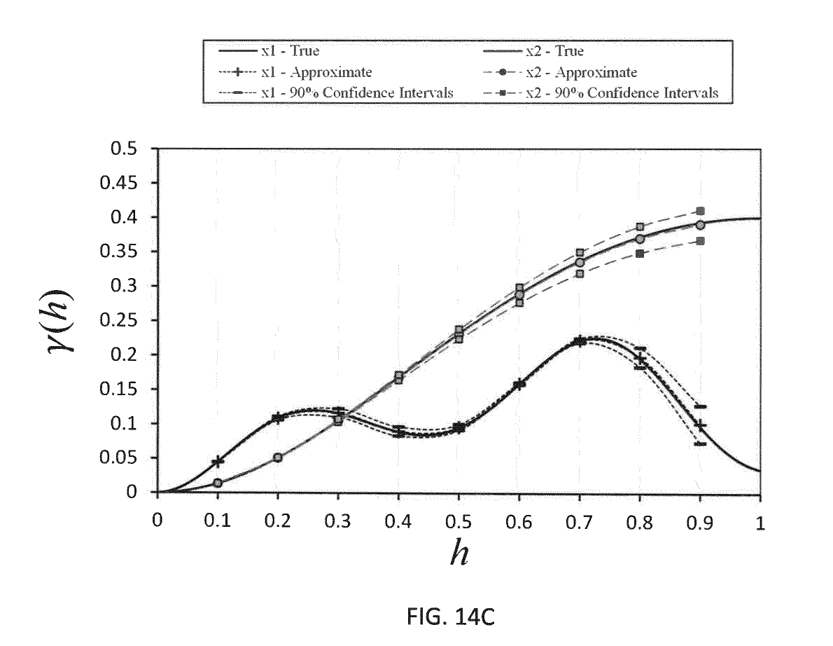

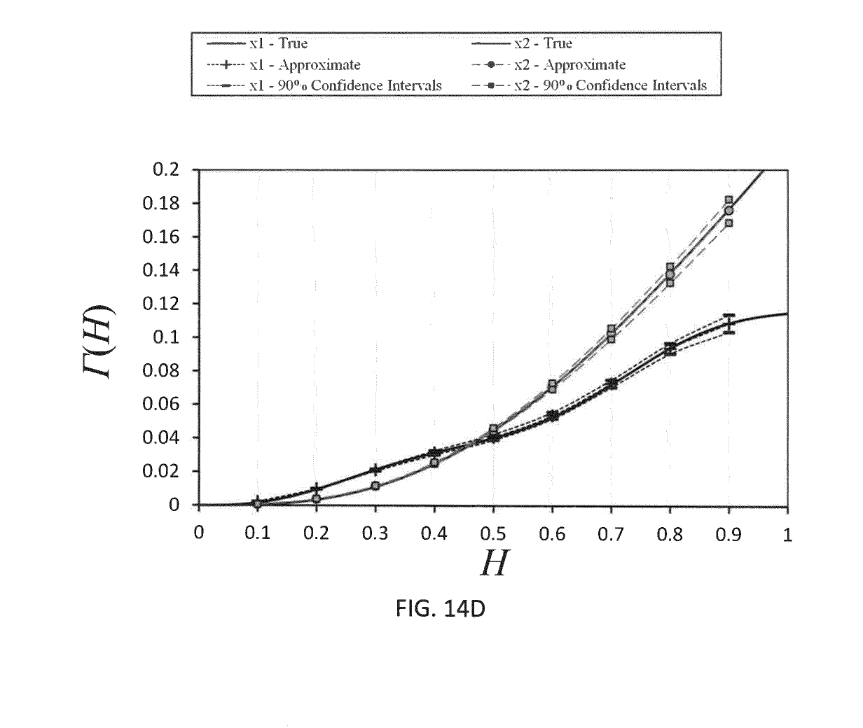

Bootstrapping is used to evaluate the level of confidence we can ascribe to the VARS results. Note again that in this case study there are no interactions between factors and so only one cross section (i.e., one star point) with a fine resolution (very small step size Δh, say Δh≦0.01) in each factor direction can be used to very accurately generate the VARS products. Accordingly, the bootstrap-based lower and upper confidence intervals for any of the factors are almost equal. For larger Δh, however, cross sections along a direction can complement each other, as the points of a cross section may not be aligned with the points of the other cross sections. FIGS. 14A-14D show examples of bootstrapping for two independent trials of VARS using Δh=0.1, one based on 10 star points (FIGS. 14A and 14B) and the other on 50 star points (FIGS. 14C and 14D). As can be seen, the 90% confidence (uncertainty) intervals are quite narrow, even for the VARS trial with only 10 star points.

### Example 2

### 5-Parameter Conceptual Rainfall-Runoff Model

The second example uses the commonly available HYMOD model to simulate the rainfall-runoff response of the 1944 km² Leaf River watershed, located north of Collins, Miss. Here, sensitivity of the Nash-Sutcliffe criterion is evaluated (i.e., goodness-of-fit of the model to observation) to variations in the five model parameters across their feasible range. The five parameters are the maximum storage capacity in the catchment, Cₘₐₓ (unit L), the degree of spatial variability of the soil moisture capacity within the catchment, bₑₓₚ (unitless), the factor distributing the flow between the two series of reservoirs, Alpha (unitless), and the residence times of the linear quick and slow reservoirs, R_{q} (unit T) and Rₛ (unit T). For simplicity of presentation, all factors were scaled so that their feasible ranges correspond to [0-1].

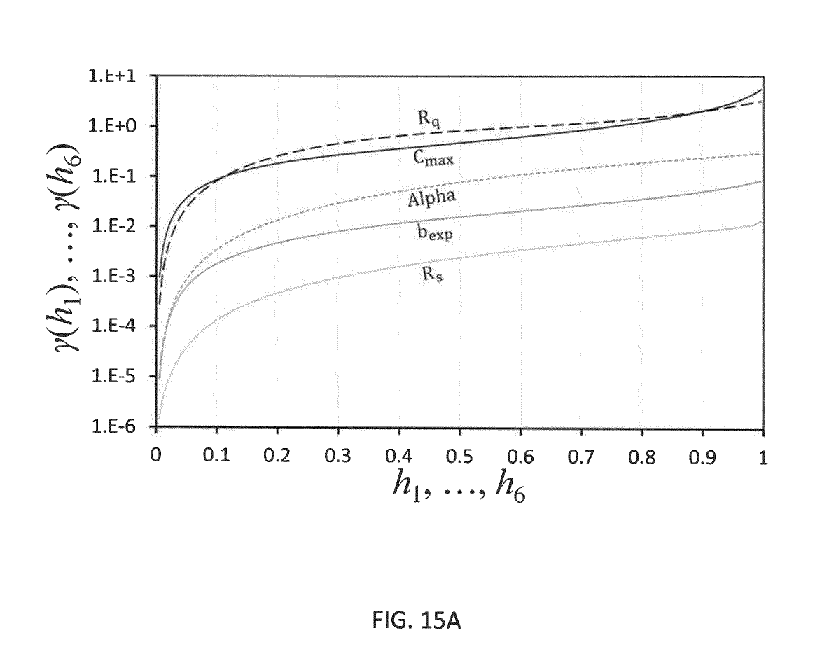

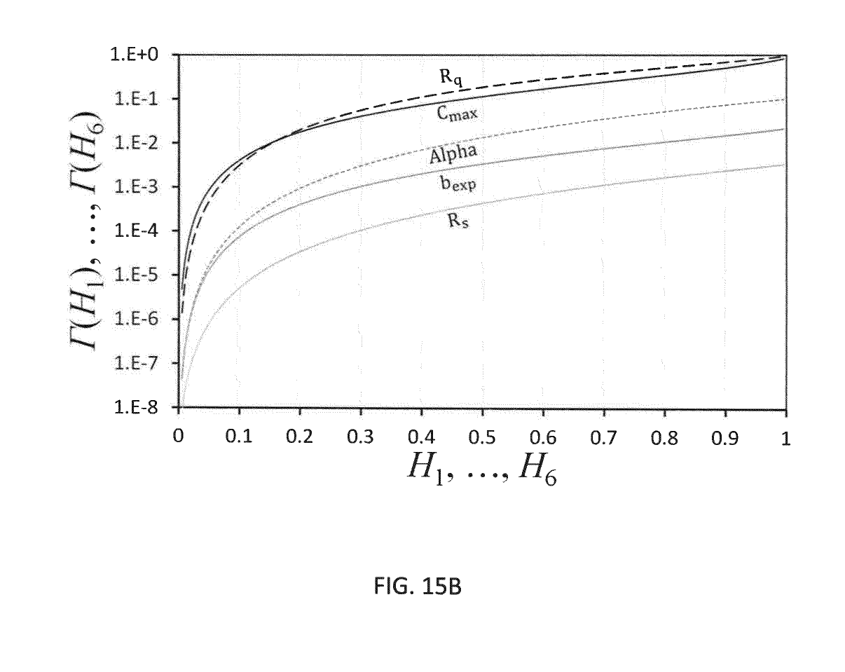

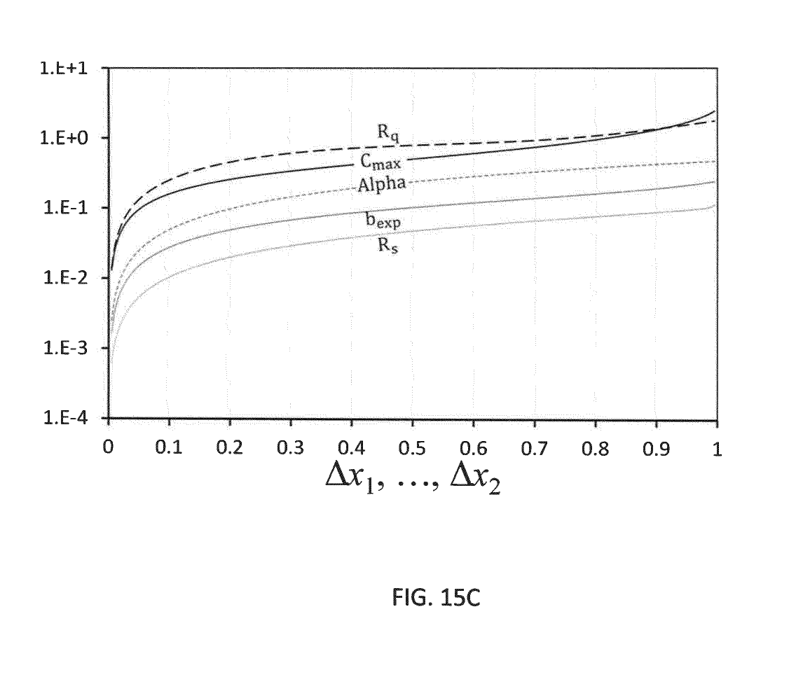

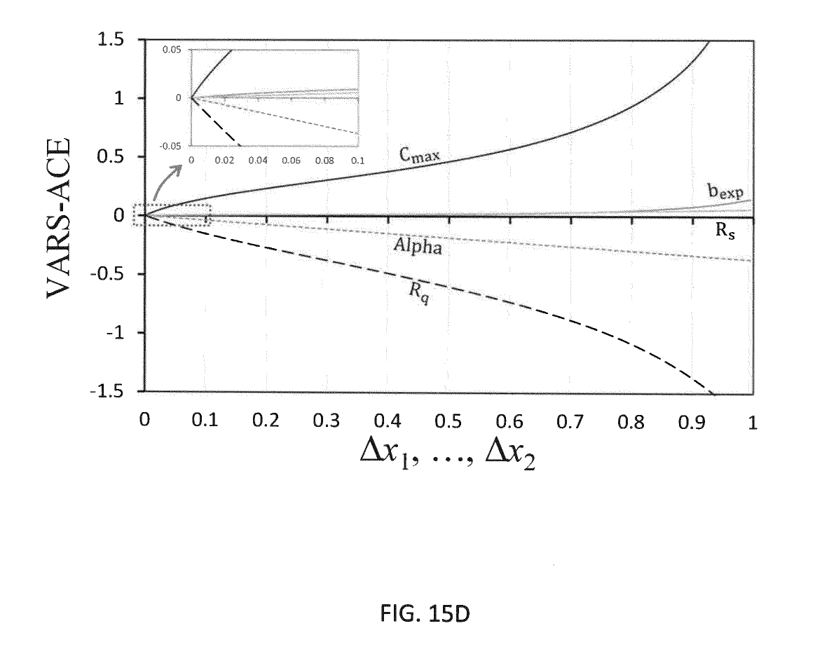

FIGS. 15A-15D show the VARS products obtained for the second example. The directional variogram of R_{q} is lower than that of Cₘₐₓ for scale range (i.e., h) 0 to about 0.1 (see FIGS. 15A-15B). However, beyond this range, the directional variogram of R_{q} is larger. The directional variograms of bₑₓₚ and Alpha are quite similar for h≦0.05, while for larger h, the variogram of Alpha becomes significantly larger. These small-scale behaviors are not reflected by VARS-ACE and VARS-ABE (see FIGS. 15C-15D).

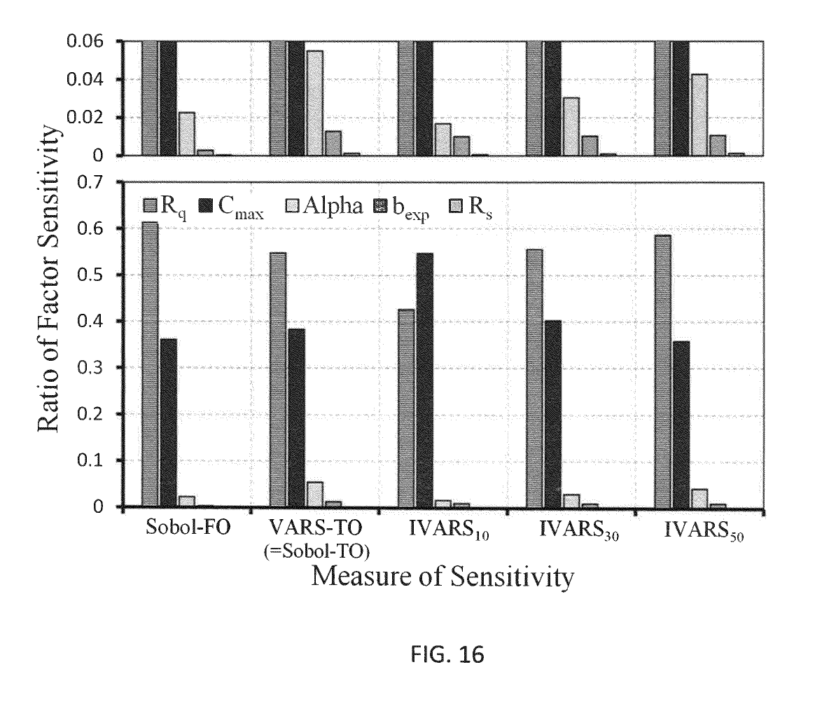

FIG. 16 compares the factor sensitivity ratios provided by different metrics for this case study. Sobol-FO, Sobol-TO (=VARS-TO), IVARS30, and IVARS50 consistently rank the parameter sensitivities as follows: R_{q}>Cₘₐₓ>Alpha>bₑₓₚ>Rₛ. However, at small scales (represented by IVARS10), we find that the sensitivity of the two most sensitive parameters is inverted (so that R_{q}<Cₘₐₓ). Overall, the parameters R_{q} and Cₘₐₓ are indicated to be significantly more sensitive than the other parameters, and Rₛ is almost insensitive. Also at smaller scales, Alpha and bₑₓₚ tend to demonstrate equal sensitivity. Note that this assessment is specific to the use of the Nash-Sutcliffe criterion as the model performance metric.

### Example 3

### 45-Parameter Land Surface Scheme-Hydrology Model

The third example is conducted utilizing the MESH modelling system which couples the Canadian Land Surface Scheme (CLASS) with land-surface parameterization and hydrological routing schemes used by WATFLOOD. The study area is the White Gull basin with a drainage area of 603 km², which is a research site of Boreal Ecosystems Atmosphere Study (BOREAS) located in Saskatchewan, Canada. The model's 45 surface and subsurface parameters were calibrated by maximizing the Nash-Sutcliffe criterion with regards to streamflow. This case study provides a rigorous test of the efficiency of the VARS approach, since the model is computationally intensive, with each model run requiring approximately 30 seconds of computer time.

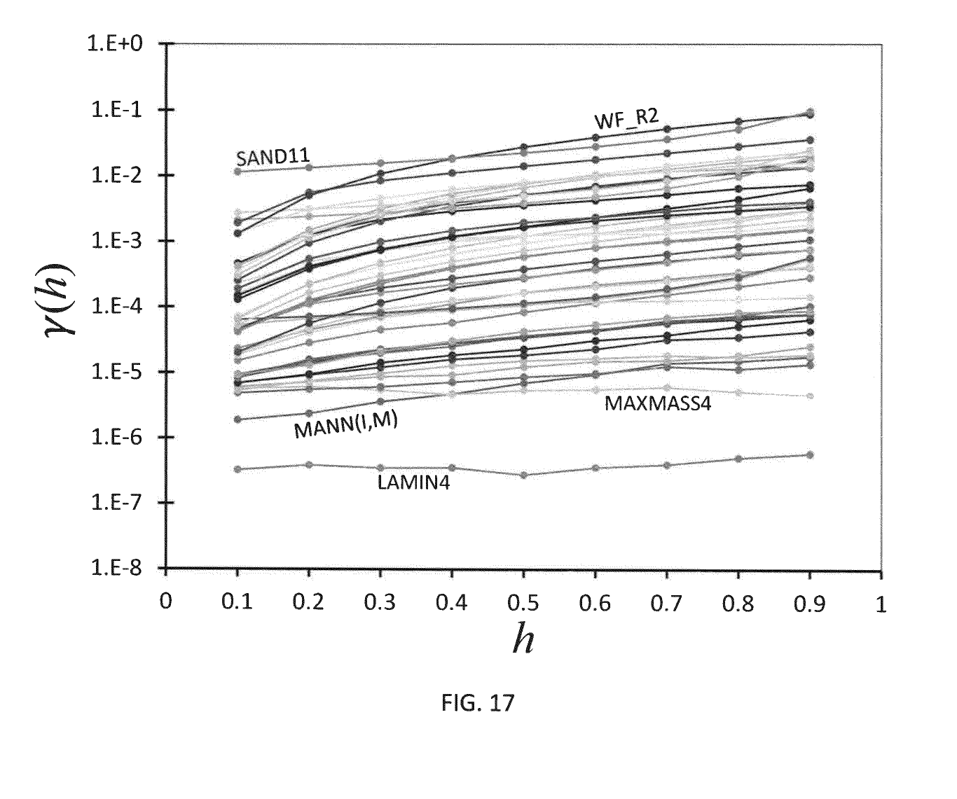

To begin, FIG. 17 shows a VARS assessment conducted using 250 star points (requiring 101,500 model runs). The 45 estimated directional parameter variograms show quite simple forms, and reveal that LAMIN4 is the least sensitive parameter. Also, most of the parameter vanograms cross one or more of the other parameter variograms, indicating different sensitivity rankings at different scales.

More importantly, the sensitivity assessments provided by the VARS, Sobol and Morris approaches at comparable computational budgets can be compared. To compute the IVARS indices (IVARS10, IVARS30 and IVARS50) and VARS-TO, the star-based sampling strategy is used with 20,300 model runs (50 center points) and 101,500 model runs (250 center points). To compute the Sobol-TO, 20,304 and 100,016 model runs are used. To compute the Morris-SQE5, 20,010 and 100,004 model runs are used.

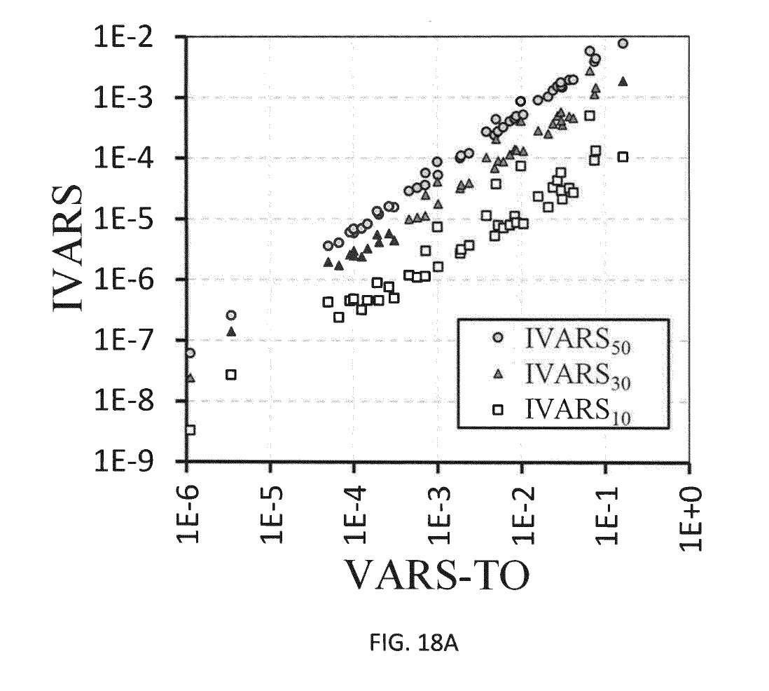

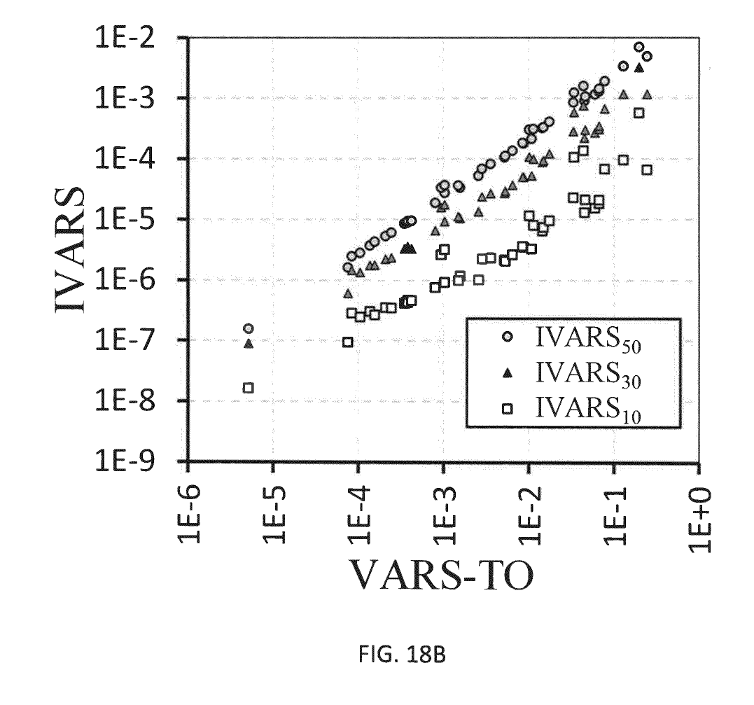

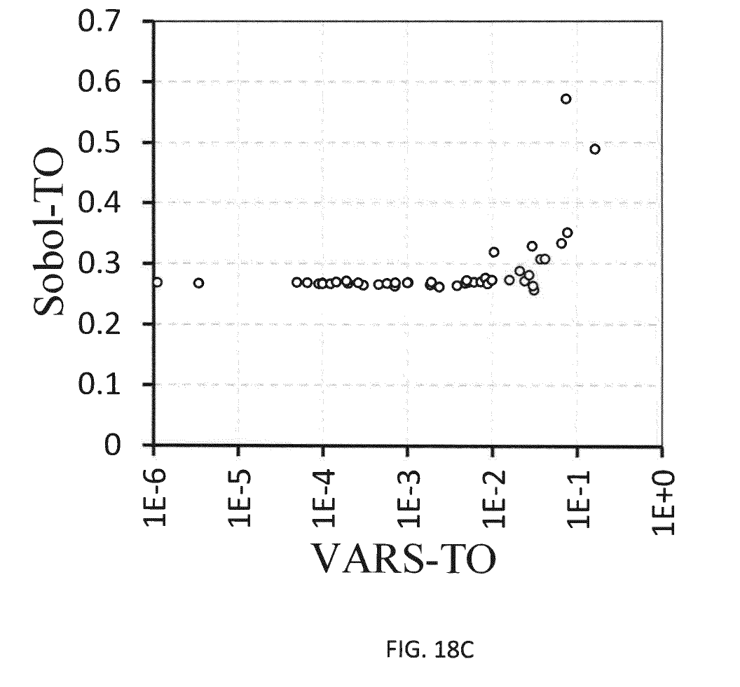

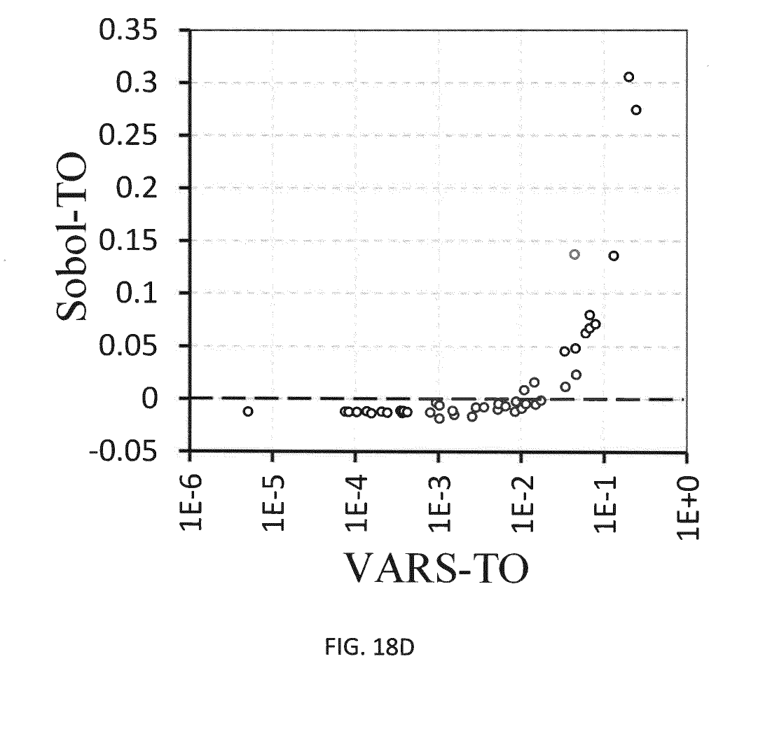

FIGS. 18A and 18B show the degree of correspondence between the IVARS sensitivity metrics at different scales and VARS-TO for each of the two computational budgets. As might be expected, the IVARS₅₀ and VARS-TO rankings correspond well, while the correspondence diminishes at shorter scales (IVAR₃₀ and IVARS₁₀). However, a comparison between VARS-TO with Sobol-TO (FIGS. 18C-18D), equivalent metrics obtained via different numerical implementations, shows that the implementation of Sobol (i.e., Sobol-TO) is unable to effectively differentiate between more than half of the parameters, even at the larger computational budget of 100,000+ model runs. In addition, these estimates of total-order effects are negative for most of the parameters (a result that is theoretically infeasible), revealing problems of numerical stability associated with the approach.

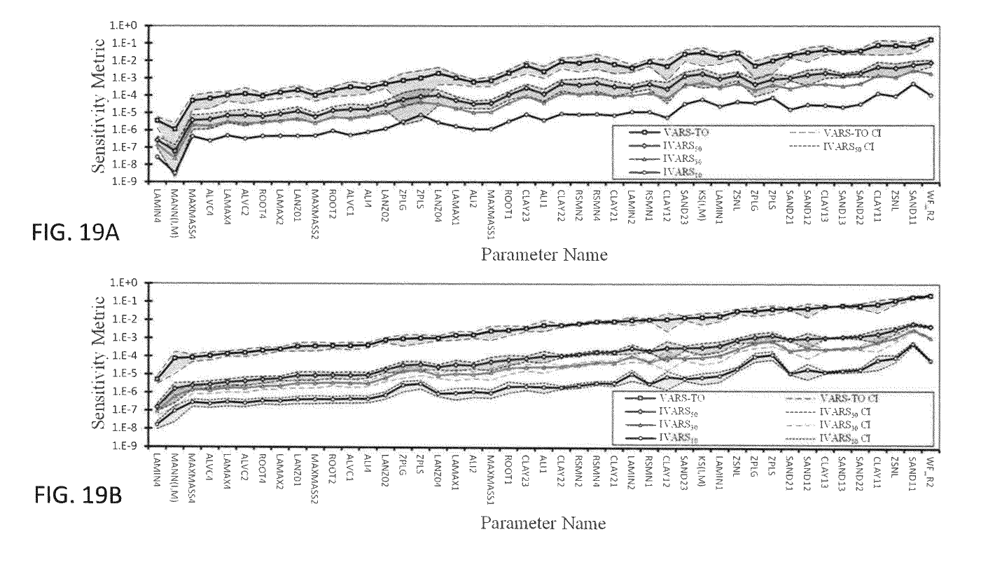

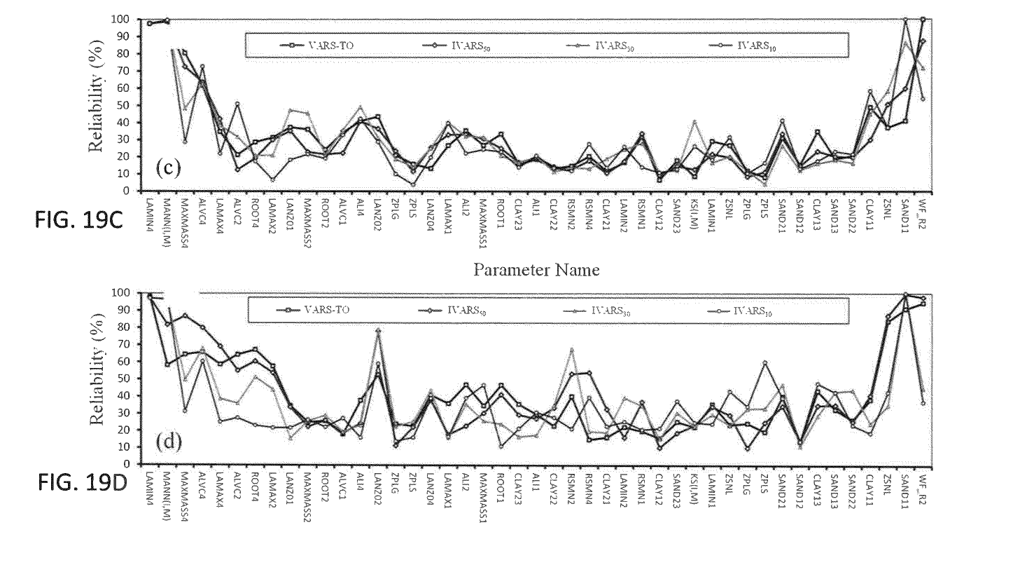

FIGS. 19A-19B show the bootstrap-based 90% confidence intervals for the VARS-based sensitivity metrics for each parameter (parameters are ordered based on VARS rankings at the larger computational budget). The confidence intervals are relatively narrow, and their widths decrease significantly with larger numbers of model runs. 19C-19D show that the bootstrap-based estimates of reliability on the parameter rankings vary from 4-100% (median=23%) for the lower computational budget and 10-100% (median=33%) for the larger budget. Taken together, these results indicate that while the metric estimates are fairly precise, their uncertainty is still large enough that the ranking of parameters having similar sensitivity can vary considerably; i.e., the true sensitivity rank of a parameter may be slightly more or less than estimated. However, it is fairly clear that LAMIN4 (minimum leaf area index of Grass) and MANN(I,M) (Manning's constant for overland flow) are the least sensitive parameters, while WF_R2 (river roughness factor) and SAND11 (% of sand soil layer 1) are the most sensitive ones.

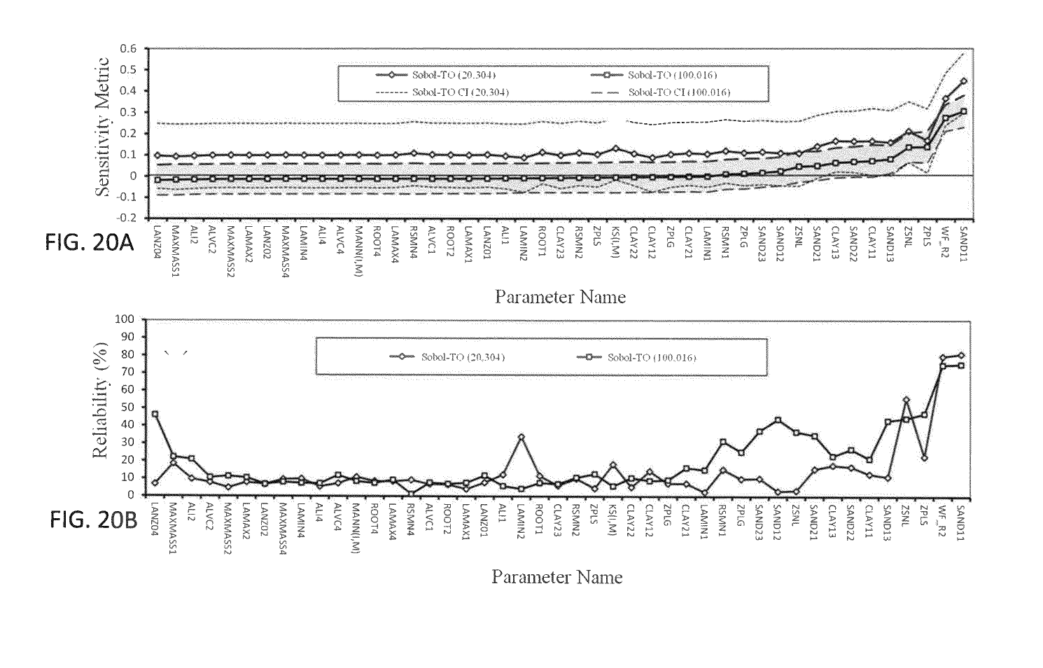

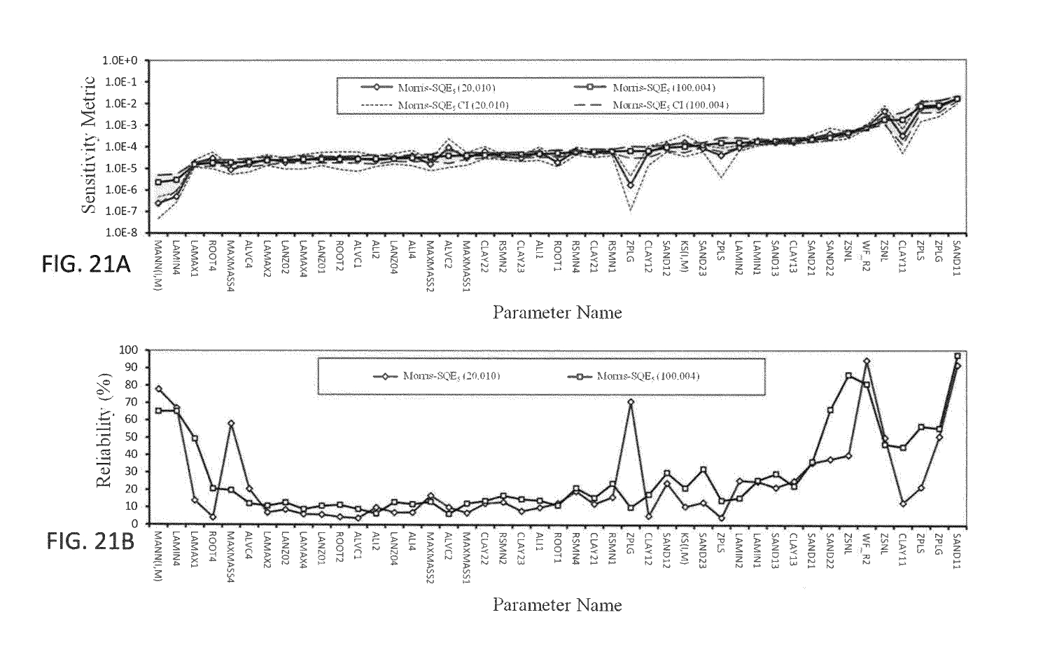

FIGS. 20A-20B and 21A-21B show similar results for the Sobol-based sensitivity metrics and the Morris-based sensitivity metrics (note that the parameter orders are different, each being based on the respective Sobol-TO or Morris-ACE5 rankings at the larger computational budget). In case of the Sobol approach, while the uncertainty in estimated metric value decreases with increasing computational budget, it remains relatively large, with the lower bounds of the confidence intervals being at negative values for most of the parameters. This results in very low reliability estimates for the parameter rankings (median=9% and 11% at lower and higher computational budgets respectively), indicating that much larger computational budgets will be needed for the Saltelli-based Sobol-TO sensitivity assessment to become sufficiently credible. In case of the Morris approach, the uncertainty in estimated sensitivity metric is substantially less than obtained using the Saltelli-based Sobol approach, but remains larger than the uncertainty estimates obtained using VARS. Accordingly, the Morris reliability estimates for parameter rankings are in general lower than those of VARS (median=13% and 17% at lower and higher computational budgets, respectively).

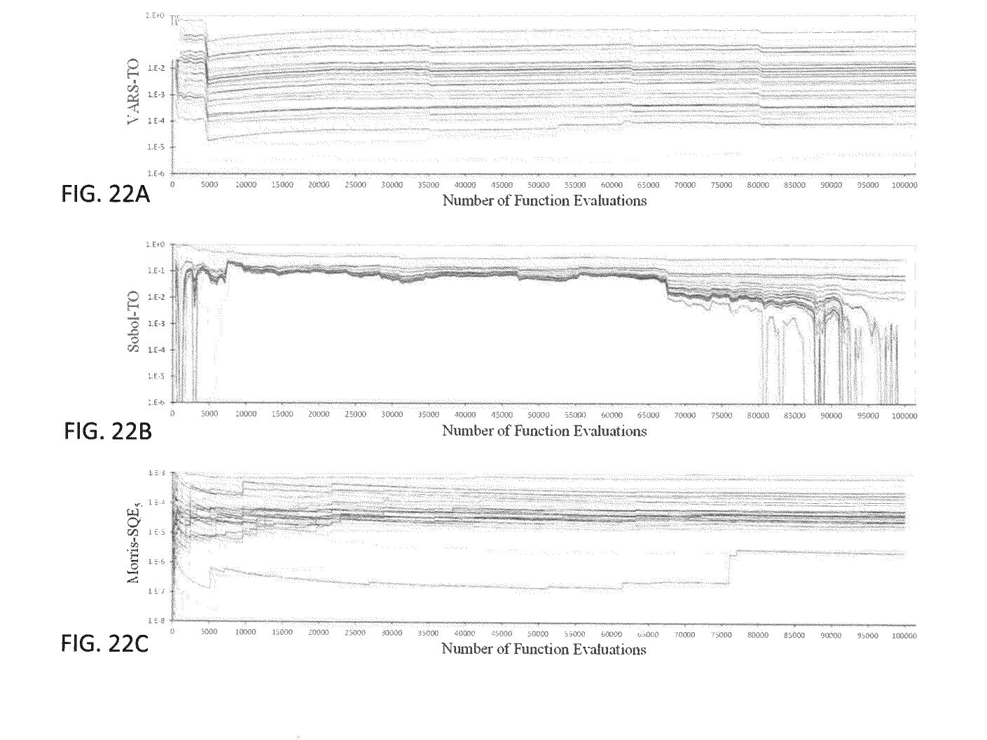

Finally, FIGS. 22A, 22B, and 22C compare the stability and robustness of implementations of VARS, Sobol, and Morris with increasing computational budget. While the VARS-based estimate of total order effect (VARS-TO) stabilizes after about 5,000 function evaluations, the Saltelli-based estimate (Sobol-TO) has yet to stabilize even after 100,000 function evaluations. These results suggest that the Saltelli-based Sobol approach may not provide reliable results for high-dimensional problems unless excessively large computational budgets are used, and that the VARS approach is at least 20 times (100,000/5,000) more efficient—probably even much more so. Compared with Saltelli-based Sobol, the Morris approach is more robust and stable. However, its factor rankings change significantly until around 40,000 model runs, and continue to change for the entire computational budget.

The described method for numerical implementation of the VARS framework, includes (1) a sampling strategy (called “star-based sampling”) to analyze cross sections of the response surface along each factor direction so as to compute estimates of VARS-based sensitivity measures, and (2) a bootstrap strategy to compute estimates of confidence intervals for each sensitivity measure and to provide reliability estimates for the inferred factors rankings. In the absence of factor interactions, the proposed implementation of VARS requires only one cross section along each factor direction to fully characterize all of the VARS-based sensitivity measures (and also the Sobol and Morris sensitivity measures).

Notably, the VARS framework appears to be both computationally efficient and statistically robust, even for high-dimensional response surfaces, providing stable estimates with a relatively small number of points sampled on the response surface (i.e., a small number of model runs). The computational efficiency is, in part, due to the fact that the VARS framework is based on the information contained in pairs of points, rather than in individual points. Because a set of k points sampled across a response surface results in C₂^{k} pairs (combinations of 2 out of k points), the information content grows very rapidly (the number of pairs grows as n(nk−1)/2≈n², where n is the rate of increase of points). So, for example if k=1,000 points we get 499,500 pairs but doubling (n=2) the number to k=2,000 points results in a 4-fold (n²=4) increase to 1,999,000 pairs, etc.

These features of VARS have been illustrated and demonstrated via three examples, the first being a synthetic test function for which the sensitivity ranking is clearly known, the second involving parameter sensitivity of a 5-parameter Conceptual Rainfall-Runoff model, and the third involving parameter sensitivity of a 45-parameter Land Surface Scheme Hydrology Model. As benchmarks to illustrate relative effectiveness and efficiency of VARS, results using an existing state-of-the-art implementation of the Sobol variance-based approach and a conventional implementation of the Morris approach are provided.

The case study results demonstrate that our proposed implementation of the VARS framework provides consistent, reliable and robust estimates of factor sensitivity at a range of scales, and at relatively low computational cost. Further, it also provides accurate estimates of the Sobol total-order effects as a side product. In regards to relative efficiency, the VARS framework was two orders of magnitude more efficient than the Sobol approach for Case Study 1 (a 6-factor response surface with no interactions) and 20 times more efficient than Sobol and Morris for Case Studies 2 and 3 (5-parameter Conceptual Rainfall-Runoff model, and 45-parameter Land Surface Scheme-Hydrology model respectively). In particular, Case Study 3 provides a powerful demonstration of the relative strength of VARS over the popular variance-based Sobol approach for high-dimensional EESMs, showing that relatively reliable estimates of parameter sensitivity can be obtained with relatively low computational budgets. It appears that, in practice, the Sobol method may not be able to provide reliable results for high-dimensional parameter sensitivity problems of this kind.

The described methods of determining global sensitivity using variograms are computationally efficient and provide a more accurate characterization of sensitivity that existing methods. It has been found to be on the order of one magnitude faster than currently available methods.

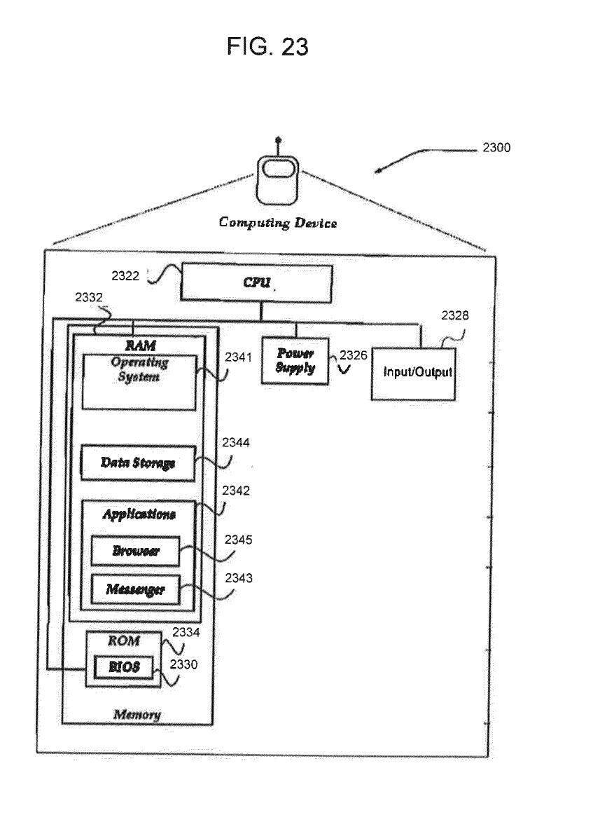

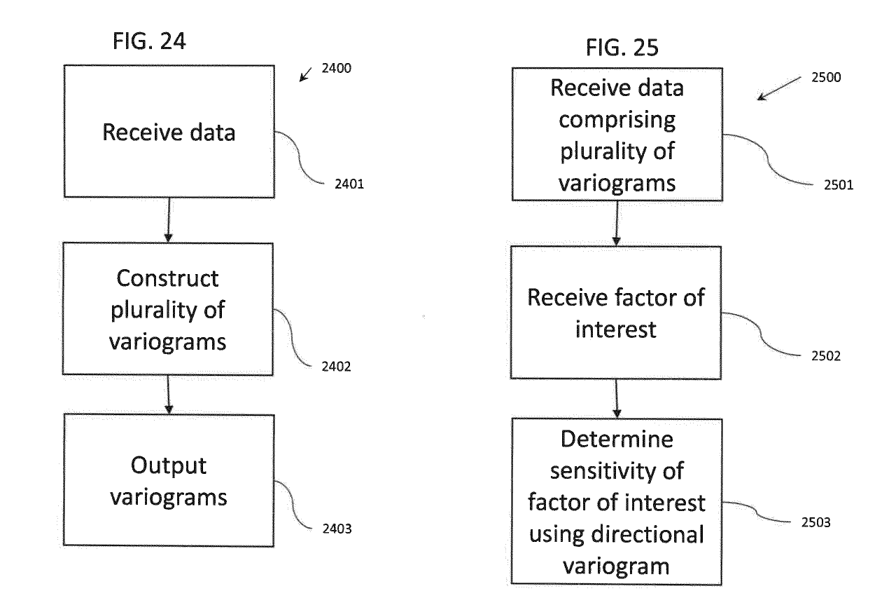

The described method of determining global sensitivity using variograms may be implemented by a computer system. FIG. 23 shows one example schematic of an embodiment of a computing device 2300 that may be used to practice the claimed subject matter. The computing device 2300 includes a memory 2330 that stores computer readable data. The memory 2330 may include random access memory (RAM) 2332 and read only memory (ROM) 2334. The ROM 2334 may include memory storing a basic input output system (BIOS) 2330 for interfacing with the hardware of the computing device 2300. The RAM 2332 may include an operating system 2341, data storage 2344, and applications 2342 including instructions for implementing functions such as the method of FIG. 24. A central processing unit (CPU) 2322 executes computer instructions to implement functions, such as the modules described in relation to FIG. 24. Input/output 2328 enables the computing device to communicate with external components such as a user or additional computing device. A power supply 2326 supplies power to the memory 2330, the CPU 2322, and other components. The CPU 2322, the memory 2330, and other devices may be interconnected by a bus 2324 operable to communicate between the different components.

FIG. 24 illustrates a high level flowchart of a method 2400 for determining the sensitivity of a model. The steps shown in the flowchart are implemented by computing device 2300, and each step may be performed by a separate module executed on the computing device 2300, or the execution of steps may be combined in one or more modules. The modules may execute on separate computing devices connected by a network, or they may execute on a single computing device. Computer executable instructions for causing the computing device to perform the steps may be stored on a non-transitory computer readable storage medium in communication with a processor.

In box 2401 data comprising a plurality of sets of input factor values and for each set, a corresponding model output value, are received. For example, the data may comprise input factor values such as control settings of a model or measured parameters such as a temperature and the model output may be a measured output of the system such as water table height. In box 2402 a plurality of integrated directional variograms based on the received data is constructed by a computer. In box 2403 the plurality of integrated directional variograms are output as an indication of the model sensitivity.

FIG. 25 illustrates another embodiment of a method 2500 for determining the sensitivity of a model. The steps shown in the flowchart are carried out by a computing device, and each step may be performed by a separate software component of a computing device, or the execution of steps may be combined in one or more software components. The software components may exist on separate computing devices connected by a network, or they may exist on a single computing device. Computer executable instructions for causing the computing device to perform the steps may be stored on a non-transitory computer readable storage medium in communication with a processor.

In box 2501 data comprising a plurality of integrated directional variograms are received. The integrated directional variograms correspond to a model for which the sensitivity is being determined. In box 2502 a factor of interest is received and in box 2503 the sensitivity for the factor of interest is evaluated using the integrated directional variogram corresponding to the factor of interest.

While various embodiments have been described above, it should be understood that they have been presented by way of example only, and not limitation. The described process of using variograms for sensitivity analysis are applicable to processes and models in any field and is not limited to the field of Environmental and Earth System Models. Furthermore, the described use of a variogram for sensitivity analysis is not limited to the specific form described herein. The form of sensitivity analysis presented is one of many possible forms to utilize variograms in this context, and the user of other forms using variograms is contemplated. For example, different sampling methods for collecting data points in the factor space in order to generate variograms is possible. It will be apparent to persons skilled in the relevant arts that various changes in form and details can be made therein without departing from the spirit and scope of the invention. Thus, the breadth and scope of the present invention should not be limited by any of the above-described exemplary embodiments, but should be defined only in accordance with the following claims and their equivalents.

1. A system for analyzing sensitivity of a model, comprising:
a computer processer;
an input in communication with the computer processor;
non-transitory memory in communication with the processor, the non-transitory memory storing computer executable instructions that when executed by a computer processor implement modules comprising:
an input module configured to receive data comprising a plurality of values of a model output and, for each value of the model output, corresponding values of input factors resulting in the model output;
a variogram construction module configured to construct a directional variogram based on the data received at the input module;
an output module configured to output the directional variogram as a representation of the model sensitivity.

2. The system of claim 1, wherein the variogram construction module is further configured to construct a directional variogram for each input factor.

3. The system of claim 1, wherein the output module is configured to display the variogram.

4. The system of claim 1, wherein the modules further comprise:
a model module configured to model a process.

5. The system of claim 4, wherein the modules further comprise:
a sampling module configured to generate a plurality of sample points for modeling the process.

6. The system of claim 4, wherein the model is configured to model an environmental system.

7. A method for analyzing the sensitivity of a model, comprising:
receiving, by a computer, a plurality of sets of input factor values and for each set, a corresponding model output value;
constructing, by a computer, a plurality of directional variograms based on the sets of input factor values and model output values;
outputting the plurality of directional variograms as an indication of model sensitivity.

8. The method of claim 7, wherein the plurality of directional variograms comprises a variogram for each input factor in the sets of input factor values.

9. The method of claim 8, wherein outputting the plurality of directional variograms comprises displaying each of the variograms on a common graph.

10. The method of claim 7, further comprising:
generating a plurality of sample points to use as input factor values.

11. The method of claim 7, further comprising:
providing, by a computer, the plurality of sets of input factor values to a model and for each set of input factor values, recording an output value of the model.

12. The method of claim 7, wherein the model is an environmental model.

13. The method of claim 7, further comprising:
normalizing the plurality of variograms.

14. The method of claim 13, wherein normalizing the plurality of variograms comprises integrating each variogram from zero to a maximum value of an input factor.

15. The method of claim 14, wherein outputting the plurality of variograms comprises outputting a plurality of values for each variogram.

16. The method of claim 15, wherein the plurality of values comprises a value at ten percent of the factor range and fifty percent of the factor range.

17. A method for analyzing the sensitivity of a process, comprising:
receiving, by a computer, a plurality of sets of input factor values and for each set, a corresponding process output value;
constructing, by a computer, a plurality of directional variograms based on the sets of input factor values and process output values;
outputting the plurality of directional variograms as an indication of process sensitivity.

18. The method of claim 17, wherein the plurality of directional variograms comprises a variogram for each input factor in the sets of input factor values.

19. The method of claim 17, further comprising:
generating a plurality of sample points to use as input factor values.

20. The method of claim 17, further comprising:
providing, by a computer, the plurality of sets of input factor values to a process and for each set of input factor values, recording an output value of the process.
